(19) United States
(12) Patent Application Publication
(10) Pub. No.: US 2026/0100677 A1
(43) Pub. Date: Apr. 9, 2026

(54) VECTOR SUMMING AMPLIFIER AND PHASE SHIFT DEVICE INCLUDING THE SAME

(71) Applicant: SAMSUNG ELECTRONICS CO., LTD., SUWON-SI, (KR)

(72) Inventors: Jaeyeon Jeong, Suwon-si (KR); Ho Kim, Busan (KR); Ilku NAM, Busan (KR); Hyunchul Park, Suwon-si (KR); Joonhoi Hur, Suwon-si (KR)

(73) Assignee: Pusan National University Industry-University Cooperation Foundation, Geumjeong-gu (KR)

(21) Appl. No.: 19/005,040

(22) Filed: Dec. 30, 2024

(30) Foreign Application Priority Data
Oct. 7, 2024 (KR) 10-2024-0136027

(51) Int. Cl. H03F 1/02; H03F 3/45; H03H 11/20

(52) U.S. Cl. CPC H03F 1/0205; H03F 3/45179; H03H 11/20; H03F 2200/294; H03F 2200/451

(57) ABSTRACT

A vector summing amplifier includes a phase control circuit configured to receive a plurality of orthogonal signals and output a differential intermediate signal having a target phase through a vector sum of at least a portion of the plurality of orthogonal signals, a gain compensation circuit configured to receive the differential intermediate signal and output a differential output signal having the target phase and a target gain, and a communication processor configured to control the phase control circuit and the gain compensation circuit. The communication processor may control a plurality of compensation transistors, included in the gain compensation circuit, based on an amplification factor corresponding to the target phase such that the gain compensation circuit outputs the differential output signal having the target gain.

### CROSS-REFERENCE TO RELATED APPLICATION(S)

This U.S. non-provisional application claims priority under 35 USC § 119 to Korean Patent Application No. 10-2024-0136027, filed on Oct. 7, 2024, in the Korean Intellectual Property Office, the disclosure of which is herein incorporated by reference in its entirety.

### TECHNICAL FIELD

Example embodiments relate to a vector summing amplifier and a phase shift device including the same.

### DISCUSSION OF RELATED ART

In the field of communications, efforts have been made to develop 5th generation (5G) communication systems to satisfy the increasing demand for wireless data traffic that has been growing since the commercialization of 4th generation (4G) communication systems. The implementation of 5G communications in millimeter-wave (mmWave) bands is taken into consideration.

Due to characteristics of millimeter waves having high frequencies, free space loss may increase. Accordingly, beamforming technology for increasing the directivity of radio waves is being used to enhance transmission efficiency.

Beamforming technology may control a phased array system provided with a plurality of antennas such that each antenna radiates waves with a predetermined phase difference, thereby controlling a beam having a directivity to be formed in a desired direction.

Recently, there has been growing demand in phased array systems for vector summing amplifiers with high-resolution phase control (achieving smaller increments of phase differences between antenna elements for beam steering) to enhance the accuracy of the directed beam.

### SUMMARY

Example embodiments provide a vector summing amplifier having a relatively small area.

According to an example embodiment, a vector summing amplifier includes a phase control circuit configured to receive a plurality of orthogonal signals and output a differential intermediate signal having a target phase through a vector sum of at least a portion of the plurality of orthogonal signals, a gain compensation circuit configured to receive the differential intermediate signal and output a differential output signal having the target phase and a target gain, and a communication processor configured to control the phase control circuit and the gain compensation circuit. The communication processor may control a plurality of compensation transistors, included in the gain compensation circuit, based on an amplification factor corresponding to the target phase such that the gain compensation circuit outputs the differential output signal having the target gain.

According to an example embodiment, a phase shift device includes an active balun configured to convert a single-phase input signal into a differential input signal, an orthogonal signal generator configured to receive the differential input signal and output a plurality of orthogonal signals, a vector summing amplifier configured to output a differential output signal having a target phase and a target gain based on the plurality of orthogonal signals, a variable gain amplifier configured to output a single-phase output signal having a conversion gain from the differential output signal, and a communication processor configured to control the vector summing amplifier and the variable gain amplifier. The vector summing amplifier may include a phase control circuit, configured to receive the orthogonal signals and output a first signal having the target phase through a vector sum of at least a portion of the plurality of orthogonal signals, and a gain compensation circuit configured to receive the first signal and output a second signal having the target phase and a target gain. The communication processor may control a plurality of compensation transistors, included in the gain compensation circuit, based on a first amplification factor corresponding to the target phase such that the gain compensation circuit outputs a signal having the target gain.

According to an example embodiment, a method of controlling a vector summing amplifier includes receiving a command comprising data on a target phase, generating a differential intermediate signal having the target phase from at least a portion of orthogonal signals using a phase control circuit in response to the command, and outputting a differential output signal having the target phase and a target gain from the differential intermediate signal using a gain compensation circuit. The outputting the differential output signal may further include controlling a gain of the differential intermediate signal based on an amplification factor stored to correspond to the target phase.

In another aspect, a vector summing amplifier includes: a phase control circuit configured to receive a plurality of orthogonal signals and output a differential intermediate signal having a target phase through a vector sum of at least a portion of the plurality of orthogonal signals; a gain compensation circuit configured to receive the differential intermediate signal and output a differential output signal having the target phase and a target gain; and a communication processor configured to control the phase control circuit and the gain compensation circuit. The phase control circuit includes a first source follower transistor and a second source follower transistor, each configured to receive a first orthogonal signal and connected in parallel with each other between a power supply voltage line and a first output node; and a first common source transistor and a second common source transistor, each configured to receive a second orthogonal signal, orthogonal to the first orthogonal signal, and connected in parallel with each other between the first output node and ground.

### BRIEF DESCRIPTION OF DRAWINGS

FIG. 1A is a block diagram of a vector summing amplifier according to an example embodiment.

FIG. 1B is a block diagram of a vector summing amplifier, further including a communication processor, according to an example embodiment.

FIG. 2 is a circuit diagram illustrating a phase control circuit included in a vector summing amplifier according to an example embodiment.

FIG. 3A is a phasor diagram illustrating signal components to output a first intermediate signal having a phase of 45 degrees through a phase control circuit according to an example embodiment.

FIG. 3B is a phasor diagram illustrating signal components to output a first intermediate signal having a phase of 135 degrees through a phase control circuit according to an example embodiment.

FIG. 3C is a phasor diagram illustrating signal components to output a first intermediate signal having a phase of 0 degrees through a phase control circuit according to an example embodiment.

FIG. 3D is a phasor diagram illustrating signal components to output a first intermediate signal having a phase of 90 degrees through a phase control circuit according to an example embodiment.

FIG. 3E is a phasor diagram illustrating signal components to output a first intermediate signal having a phase of 22.5 degrees through a phase control circuit according to an example embodiment.

FIG. 4 is a circuit diagram of a gain compensation circuit included in a vector summing amplifier according to an example embodiment.

FIG. 5 is a phasor diagram illustrating signal components to output a first output signal having a target gain through a gain compensation circuit according to an example embodiment.

FIG. 6 is a block diagram illustrating a vector summing amplifier further including an intermediate transformer and an output transformer, according to an example embodiment.

FIG. 7 is a block diagram of a phase shift device according to an example embodiment.

FIG. 8 is a flowchart illustrating a method of controlling a vector summing amplifier according to an example embodiment.

FIG. 9 is a flowchart illustrating a method of compensating for a gain of a differential intermediate signal to output a differential output signal, according to an example embodiment.

FIG. 10 is a block diagram of an electronic device according to an example embodiment.

FIG. 11 is a block diagram of an IoT device including an electronic device according to an example embodiment.

FIG. 12 is a block diagram of a mobile terminal to which an electronic device according to an example embodiment is applied.

### DETAILED DESCRIPTION

Hereinafter, example embodiments will be described with reference to the accompanying drawings.

Terms such as “first”, “second”, or the like, may be used to refer to various elements regardless of the order and/or the priority and to distinguish the relevant elements from other elements, but do not limit the elements.

Herein, phrases such as “output signal having a target gain” means that the output signal is generated by an amplifier that amplifies an input signal at the target gain to produce the output signal as an amplified version of the input signal. Similarly, a phrase such as “gain of a differential intermediate signal” means an amount by which the differential intermediate signal is amplified by an amplifier having that gain.

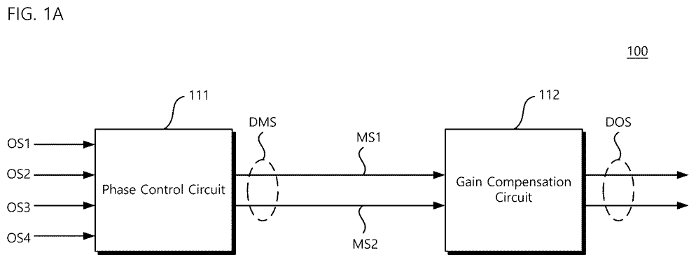

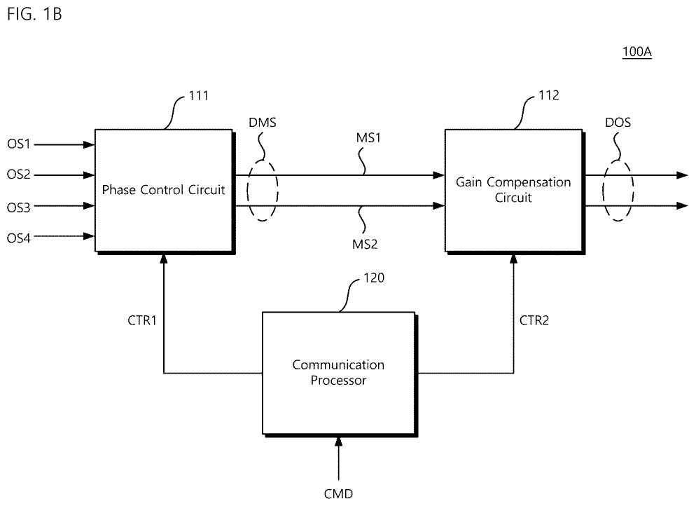

FIG. 1A is a block diagram of a vector summing amplifier according to an example embodiment. FIG. 1B is a block diagram of a vector summing amplifier, further including a communication processor, according to an example embodiment.

Referring to FIG. 1A, a vector summing amplifier 100 according to an example embodiment may include a phase control circuit 111 and a gain compensation circuit 112.

The vector summing amplifier 100 may include a phase control circuit 111 outputting a differential intermediate signal DMS from a plurality of orthogonal signals OS1, OS2, OS3, and OS4.

The phase control circuit 111 according to an example embodiment may receive a plurality of orthogonal signals OS1, OS2, OS3, and OS4 that are orthogonal to each other. Orthogonal signals may be understood as signals that, when combined or added together, do not interfere with one another. For instance, in one application, two of the orthogonal signals OS1-OS4 may be in-phase (I) and quadrature (Q) signals, and the other two signals may “Ibar” and “Qbar” signals that have opposite phase to the I and Q signals, respectively. As a result, the set of four orthogonal signals OS1-OS4 may be a pair of differential I and Q signals, where the I and Ibar signals form an “I differential signal” and the Q and Qbar signal forms a “Q differential signal”. The use of such differential signals may result in reduced noise, lower power consumption, etc. This particular case will be described in more detail later. The I and Q signals may be useful in wireless communications applications such as for applying target phases to respective antenna elements for beam steering. The I and Q signals may also be useful in digital modulation applications to generate phase shift keyed (PSK) or amplitude shift keyed (ASK) signals.

The phase control circuit 111 may receive the first orthogonal signal OS1 and the second orthogonal signal OS2, orthogonal to the first orthogonal signal OS1. In addition, the phase control circuit 111 may receive a third orthogonal signal OS3, having a phase opposite to a phase of the first orthogonal signal OS1, and a fourth orthogonal signal OS4 having a phase opposite to a phase of the second orthogonal signal OS2.

For example, the first orthogonal signal OS1 may have a phase of 0 degrees (a reference phase, such as the phase of an I signal), the second orthogonal signal OS2 may have a phase of 90 degrees (e.g., the phase of a Q signal), the third orthogonal signal OS3 may have a phase of 180 degrees (e.g., the phase of an Ibar signal), and the fourth orthogonal signal OS4 may have a phase of 270 degrees (e.g. −90 degrees, the phase of a Qbar signal), but example embodiments are not limited thereto.

In addition, the phase control circuit 111 may output a differential intermediate signal DMS having a target phase from the plurality of orthogonal signals OS1, OS2, OS3, and OS4.

For example, the phase control circuit 111 may output a differential intermediate signal DMS having a target phase through a vector sum of at least a portion of the orthogonal signals OS1, OS2, OS3, and OS4.

For example, the phase control circuit 111 may output a first intermediate signal MS1 having a phase of 45 degrees through a vector sum of the first orthogonal signal OS1 and the second orthogonal signal OS2.

For example, the phase control circuit 111 may output a first intermediate signal MS1 having a phase of 22.5 degrees through a vector sum of the first orthogonal signal OS1 and the second orthogonal signal OS2 having different gains.

In addition, the phase control circuit 111 may output a second intermediate signal MS2, differential to the first intermediate signal MS1.

In addition, the vector summing amplifier 100 may include a gain compensation circuit 112 connected to the phase control circuit 111.

The gain compensation circuit 112 may receive and amplify a differential intermediate signal DMS at a certain gain to output a differential output signal DOS having a target radio frequency (RF) power.

For example, the gain compensation circuit 112 may receive a differential intermediate signal DMS having a target phase. In addition, the gain compensation circuit 112 may adjust a gain of the differential intermediate signal DMS having a target phase to output a differential output signal DOS “having a target gain”. In other words, as noted in the term definition earlier, the gain of the gain compensation circuit 112, which amplifies the differential intermediate signal, is adjusted at the target gain to produce the signal DOS as an amplified version of the signal DMS.

Referring to FIG. 1B, a vector summing amplifier 100A according to an example embodiment may further include a communication processor 120 controlling at least a portion of the phase control circuit 111 and the gain compensation circuit 112. The vector summing amplifier 100A may be understood to include the configuration of the vector summing amplifier 100 illustrated in FIG. 1A.

The communication processor 120 may execute, for example, software or a program to control at least one other component (for example, the phase control circuit 111 or the gain compensation circuit 112) of the vector summing amplifier 100A and perform various data processing or computations. The communication processor 120 may include a central processing unit or a microprocessor, and may control the overall operation of the vector summing amplifier 100A. Accordingly, the operation performed by the vector summing amplifier 100A may be understood to be performed under the control of the communication processor 120.

According to an example embodiment, the communication processor 120 may include an algorithm for controlling the phase control circuit 111 and/or the gain compensation circuit 112. For example, the algorithm may be software code programmed within the communication processor 120. In another example, the algorithm may be hardcoded within the communication processor 120.

The communication processor 120 may control the phase control circuit 111 through a first control signal CTR1, based on the algorithm.

According to an example embodiment, the communication processor 120 may control the phase control circuit 111 to output a differential intermediate signal DMS having a target phase in response to a command CMD including data indicating the target phase.

For example, the command CMD may be understood to be transmitted from an entity (for example, an application processor) external of the vector summing amplifier 100A.

For example, the communication processor 120 may control at least a portion of the plurality of transistors included in the phase control circuit 111 such that the phase control circuit 111 outputs a differential intermediate signal DMS having a target phase.

For example, when the target phase is 45 degrees, the communication processor 120 may turn on a transistor receiving the first orthogonal signal OS1 and a transistor receiving the second orthogonal signal OS2. In addition, the communication processor 120 may turn off a transistor that receives the third orthogonal signal OS3 and a transistor receiving the fourth orthogonal signal OS4.

Accordingly, the phase control circuit 111 may output a first intermediate signal MS1 having a phase of 45 degrees according to the vector sum of the first orthogonal signal OS1 and the second orthogonal signal OS2.

For example, when the target phase is 22.5 degrees, the communication processor 120 may turn on two transistors receiving the first orthogonal signal OS1 and a single transistor receiving the second orthogonal signal OS2. In addition, the communication processor 120 may turn off the transistor receiving the third orthogonal signal OS3 and the transistor receiving the fourth orthogonal signal OS4.

Accordingly, the phase control circuit 111 may output a first intermediate signal MS1 having a phase of 22.5 degrees according to the vector sum of the first orthogonal signal OS1 and the second orthogonal signal OS2.

For example, the communication processor 120 may control the phase control circuit 111 to output a differential intermediate signal DMS having a target phase according to a vector sum of at least a portion of the plurality of orthogonal signals OS1, OS2, OS3, and OS4.

In addition, the communication processor 120 may control the gain compensation circuit 112 to output a differential output signal DOS having a target phase and a target gain.

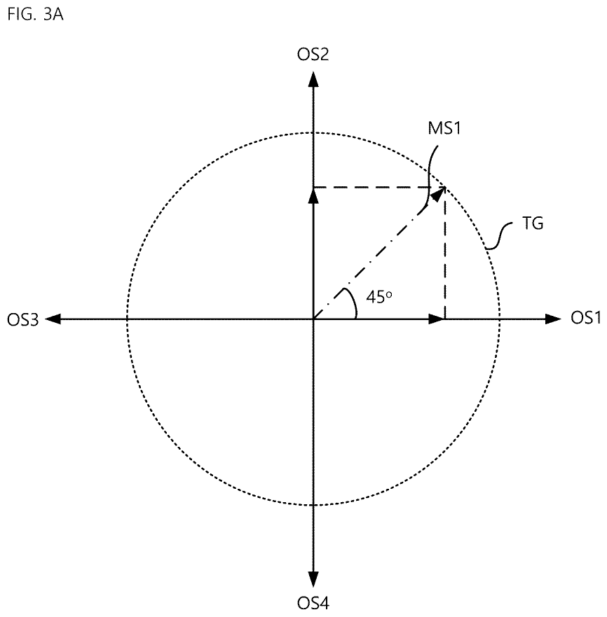

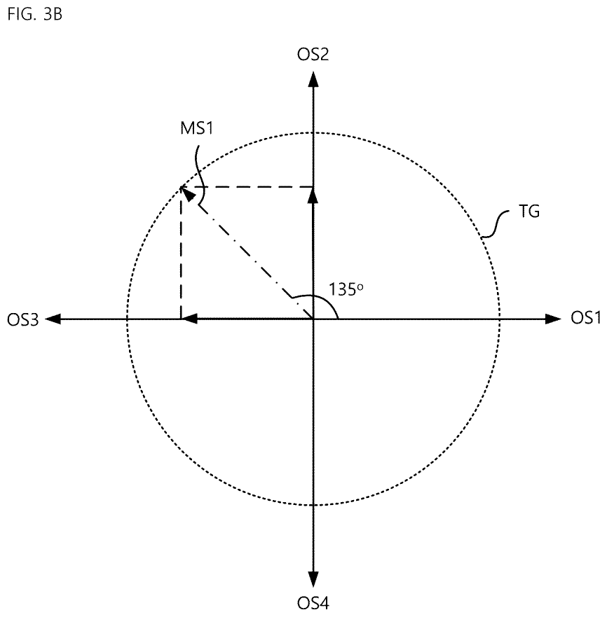

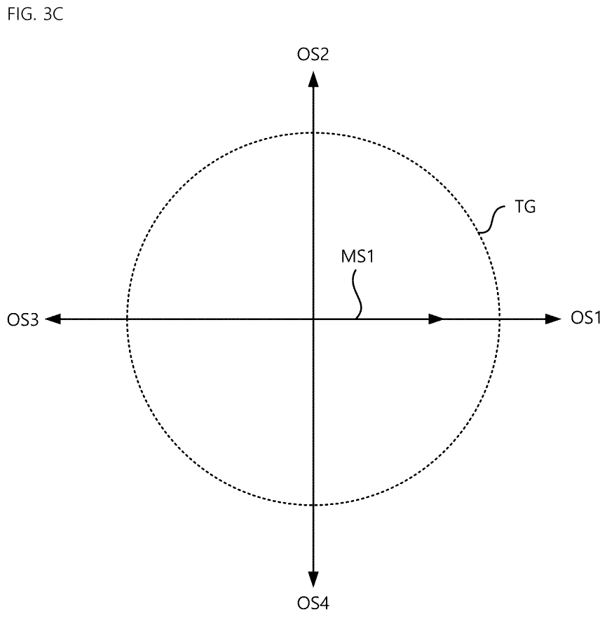

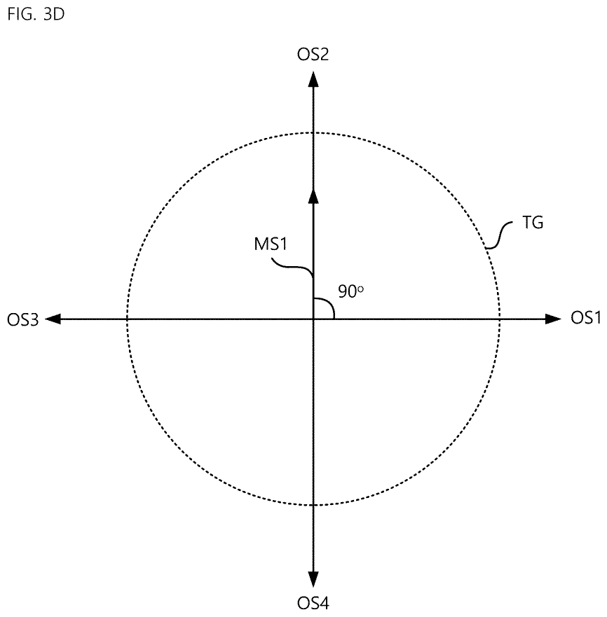

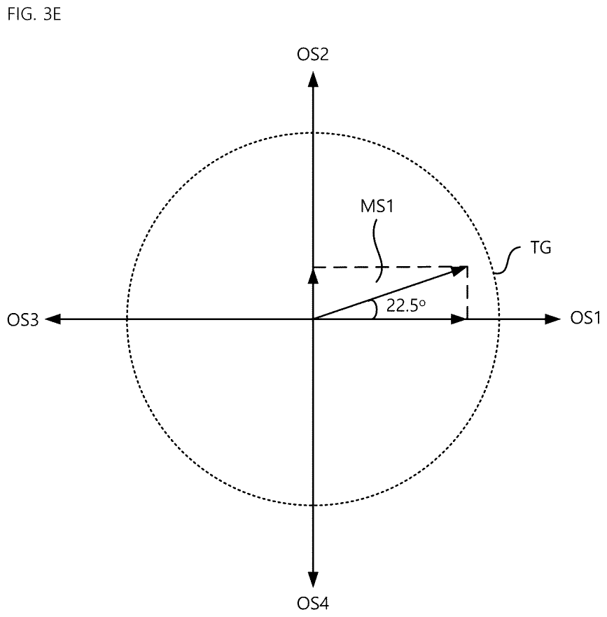

The communication processor 120 may control the gain of the differential intermediate signal DMS, using the gain compensation circuit 112, by an amplification factor (i.e., gain) corresponding to the target phase. By using an amplification factor corresponding to the target phase in some embodiments, uniform signal power can be attained for each of the target phase conditions. (As will be understood below in connection with FIGS. 3A-3E, RF power of an intermediate signal to be amplified by the gain compensation circuit 112 may vary based on the target phase.) The communication processor 120 may control the gain of the differential intermediate signal DMS having a target phase according to an amplification factor corresponding to the target phase to output a differential output signal DOS having a target phase and a target gain.

When the target phase is 22.5 degrees, the communication processor 120 may amplify the gain of the differential intermediate signal DMS, using the gain compensation circuit 112, by an amplification factor corresponding to 22.5 degrees and output the amplified gain as a differential output signal DOS.

The communication processor 120 may control the gain compensation circuit 112 through a second control signal CTR2. The second control signal CTR2 may be understood to include code for controlling the gain compensation circuit 112 according to an amplification factor corresponding to the target phase.

Therefore, the communication processor 120 according to an example embodiment may control the gain compensation circuit 112 based on the second control signal CTR2 corresponding to the target phase in response to a command CMD including data indicating the target phase.

For example, when the target phase is 90 degrees, the communication processor 120 may control the gain compensation circuit 112 through the second control signal CTR2 including code for controlling the gain compensation circuit 112 according to an amplification factor corresponding to 90 degrees.

The communication processor 120 according to an example embodiment may store data related to the code included in the second control signal CTR2. For example, the communication processor 120 may store data indicating a code (“code data”) for controlling the gain compensation circuit 112 according to an amplification factor corresponding to the target phase.

According to an example embodiment, code data included in the second control signal CTR2 may be stored in a component, separate from the communication processor 120. For example, the communication processor 120 may load code data of the second control signal CTR2 stored in an internal storage space of the vector summing amplifier 100A in response to the command CMD.

However, the component in which data related to the second control signal CTR2 corresponding to the target phase is stored is not limited to the above examples.

According to an example embodiment, the communication processor 120 may control at least a portion of the plurality of compensation transistors included in the gain compensation circuit 112 through the second control signal CTR2 such that the gain compensation circuit 112 outputs a differential output signal DOS having a target gain.

The communication processor 120 may control at least a portion of compensation transistors receiving the first intermediate signal MS1 and compensation transistors receiving the second intermediate signal MS2, through the second control signal CTR2.

When the gain of the first intermediate signal MS1 is less than the target gain, the communication processor 120 may turn on at least a portion of the compensation transistors receiving the first intermediate signal MS1 to increase a gain of a signal output from the gain compensation circuit 112.

When the gain of the first intermediate signal MS1 is greater than the target gain, the communication processor 120 may turn on at least a portion of the compensation transistors receiving the second intermediate signal MS2 to decrease the gain of the signal output from the gain compensation circuit 112.

The communication processor 120 may control the gain of the differential intermediate signal DMS having a target phase through the gain compensation circuit 112 to generate a differential output signal DOS having a target phase and a target gain.

Referring to the above-described configuration, the communication processor 120 according to an example embodiment may control the phase control circuit 111 to generate a differential intermediate signal DMS having a target phase through a vector sum of the plurality of orthogonal signals OS1, OS2, OS3, and OS4.

In addition, the communication processor 120 may control the gain of the differential intermediate signal DMS having a target phase through the gain compensation circuit 112 to output a differential output signal DOS having a target phase and a target gain.

The communication processor 120 may control the gain compensation circuit 112 according to a control signal (or an amplification factor) corresponding to the phase of the differential intermediate signal DMS to achieve a uniform target gain (over a desired input signal level range and/or a desired frequency range) for the differential output signal DOS.

As a result, the vector summing amplifiers 100 and 100A may be implemented without transistors otherwise required in conventional vector summing amplifiers to generate a signal in an opposite direction of the differential intermediate signal DMS, allowing for uniform gain in the differential output signal DOS.

The vector summing amplifiers 100 and 100A according to an example embodiment may be designed with relatively fewer transistors, compared to the case in which a signal in an opposite direction of the differential intermediate signal DMS is generated to achieve a uniform gain for the differential output signal DOS.

Further, the above-described configuration may allow the vector summing amplifiers 100 and 100A according to an example embodiment to have and occupy a relatively small area.

In addition, the vector summing amplifiers 100 and 100A according to an example embodiment may include a relatively small number of transistors to reduce performance degradation caused by parasitic elements of each transistor.

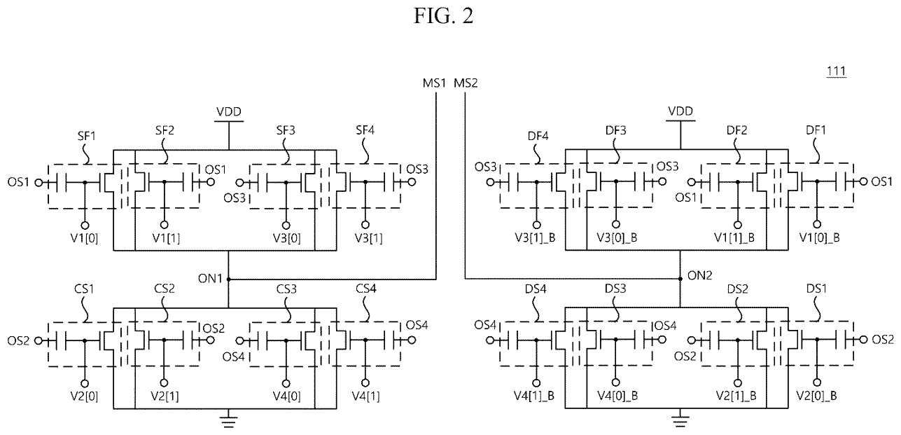

FIG. 2 is a circuit diagram illustrating a phase control circuit included in a vector summing amplifier according to an example embodiment. FIG. 3A is a phasor diagram illustrating signal components to output a first intermediate signal having a phase of 45 degrees through a phase control circuit according to an example embodiment. FIG. 3B is a phasor diagram illustrating signal components to output a first intermediate signal having a phase of 135 degrees through a phase control circuit according to an example embodiment. FIG. 3C is a phasor diagram illustrating signal components to output a first intermediate signal having a phase of 0 degrees through a phase control circuit according to an example embodiment. FIG. 3D is a phasor diagram illustrating signal components to output a first intermediate signal having a phase of 90 degrees through a phase control circuit according to an example embodiment. FIG. 3E is a phasor diagram illustrating signal components to output a first intermediate signal having a phase of 22.5 degrees through a phase control circuit according to an example embodiment.

Referring to FIG. 2, a phase control circuit 111 according to an example embodiment may include a plurality of source follower transistors SF1, SF2, SF3, and SF4 and a plurality of common source transistors CS1, CS2, CS3, and CS4 (each being illustrated with a series capacitor at its gate receiving an input signal). The phase control circuit 111 may further include a plurality of differential source follower transistors DF1, DF2, DF3, and DF4 and a plurality of differential common source transistors DS1, DS2, DS3, and DS4 (each likewise illustrated with a series capacitor at its gate).

For example, the phase control circuit 111 may include a first source follower transistor SF1 and a second source follower transistor SF2, each receiving the same first orthogonal signal OS1, and connected in parallel with each other between a power supply voltage VDD and a first output node ON1. Note that the transistors SF1 and SF2 may be considered source follower transistors because they're part of a source follower circuit topology. In this topology, the input signal enters the gate and the output signal exits the source. Thus, the source (lower output terminal in FIG. 2) is connected to and drives current to an output load (here, the input of the gain compensation circuit 112 connected to the node ON1). Further, because the input signal is applied to the gate and the drain is directly connected to a power supply voltage VDD, it is considered “common” to both the input and the output. An analogous explanation applies to the other source follower transistors SF3 and SF4.

The first source follower transistor SF1 may be turned on or off by a control bit voltage (“control bit”) V1[0], and the second source follower transistor SF2 may be turned on or off by a control bit V1[1].

The phase control circuit 111 may include a first common source transistor CS1 and a second common source transistor CS2 that receive the second orthogonal signal OS2 and are connected in parallel to each other between a first output node ON1 and ground. Note that transistors CS1 and CS2 may be considered common source transistors because they're part of a common source circuit topology, in which the signal enters the gate and exits the drain. Here, the drain is the upper output terminal in FIG. 2, and is connected to the output load, i.e., the input of the gain compensation circuit 112, while the source is connected to ground and is “common” to both the input signal and the output signal.

The first common source transistor CS1 may be turned on or off by a control bit V2[0], and the second common source transistor CS2 may be turned on or off by a control bit V2[1].

The first source follower transistor SF1 and the first common source transistor CS1 may be connected in series between the power supply voltage VDD and ground. Similarly, the second source follower transistor SF2 and the second common source transistor CS2 may be connected in series between the power supply voltage VDD and ground.

For example, the source follower transistors SF1 and SF2 receiving the first orthogonal signal OS1 and the common source transistors CS1 and CS2 receiving the second orthogonal signal OS2 may share a current path connected from the power supply voltage VDD to ground.

Accordingly, the first orthogonal signal OS1 and the second orthogonal signal OS2 may share a current path connected from the power supply voltage VDD to the ground.

In addition, the phase control circuit 111 may include the third source follower transistor SF3 and the fourth source follower transistor SF4, each receiving the third orthogonal signal OS3 and connected in parallel between the power supply voltage VDD and the first output node ON1.

The third source follower transistor SF3 may be turned on or off by a control bit V3[0], and the fourth source follower transistor SF4 may be turned on or off by a control bit V3[1].

In addition, the phase control circuit 111 may include the third common source transistor CS3 and the fourth common source transistor CS4, each receiving the fourth orthogonal signal OS4 and are connected in parallel between the first output node ON1 and the ground.

The third common source transistor CS3 may be turned on or off by a control bit V4[0], and the fourth common source transistor CS4 may be turned on or off by a control bit V4[1].

The third source follower transistor SF3 and the third common source transistor CS3 may be connected in series between a power supply voltage VDD and ground. Similarly, the fourth source follower transistor SF4 and the fourth common source transistor CS4 may be connected in series between the power supply voltage VDD and the ground.

The source follower transistors SF3 and SF4 receiving the third orthogonal signal OS3 and the common source transistors CS3 and CS4 receiving the fourth orthogonal signal OS4 may share a current path connected from the power supply voltage VDD to the ground.

Accordingly, the third orthogonal signal OS3 and the fourth orthogonal signal OS4 may share a current path connected from the power supply voltage VDD to the ground.

The phase control circuit 111 may output a first intermediate signal MS1 through the first output node ON1 based on a vector sum of at least a portion of the first orthogonal signal OS1, the second orthogonal signal OS2, the third orthogonal signal OS3, and the fourth orthogonal signal OS4.

The phase control circuit 111 may output the first intermediate signal MS1 based on a vector sum of at least a portion of the first orthogonal signal OS1, the second orthogonal signal OS2, the third orthogonal signal OS3, and the fourth orthogonal signal OS4 under the control of the communication processor 120.

For example, referring to FIG. 2 and FIG. 3A, the communication processor 120 may turn on the first source follower transistor SF1, the second source follower transistor SF2, the first common source transistor CS1, and the second common source transistor CS2.

In addition, the communication processor 120 may turn off the third source follower transistor SF3, the fourth source follower transistor SF4, the third common source transistor CS3, and the fourth common source transistor CS4.

As a result, when the input signals OS1 and OS2 have equal amplitude, the phase control circuit 111 may output a first intermediate signal MS1 having a phase of 45 degrees through the first output node ON1 under the above-described control of the communication processor 120. For instance, for I and Q signals representing digitally modulated signals such as PSK and ASK signals, the x-axis may be the I axis and the y-axis may be the Q axis. An intermediate or output signal having a phase of 45 degrees corresponds to the I and Q signal components being positive and having equal amplitude, and this may represent a predetermined sequence of ones and/or zeroes, which may be decoded with suitable demodulation circuitry. Likewise, the signal combinations of FIGS. 3B-3E discussed below may also correspond to different respective binary numbers for an I-Q signal based digital modulation application.

For example, referring to FIG. 2 and FIG. 3B, the communication processor 120 may turn on the third source follower transistor SF3, the fourth source follower transistor SF4, the first common source transistor CS1, and the second common source transistor CS2.

In addition, the communication processor 120 may turn off the first source follower transistor SF1, the second source follower transistor SF2, the third common source transistor CS3, and the fourth common source transistor CS4.

As a result, when the input signals OS2 and OS3 have equal amplitude, the phase control circuit 111 may output a first intermediate signal MS1 having a phase of 135 degrees through the first output node ON1 under the above-described control of the communication processor 120.

For example, referring to FIG. 2 and FIG. 3C, the communication processor 120 may turn on the first source follower transistor SF1 and the second source follower transistor SF2.

In addition, the communication processor 120 may turn off the third source follower transistor SF3, the fourth source follower transistor SF4, the first common source transistor CS1, the second common source transistor CS2, the third common source transistor CS3, and the fourth common source transistor CS4.

As a result, the intermediate signal MS1 may be composed entirely of the input signal OS1 applied to the first and second source followers SF1 and SF2. Thus, the phase control circuit 111 may output the first intermediate signal MS1 having a phase of 0 degrees through the first output node ON1 under the above-described control of the communication processor 120.

For example, referring to FIG. 2 and FIG. 3D, the communication processor 120 may turn on the first common source transistor CS1 and the second common source transistor CS2.

In addition, the communication processor 120 may turn off the first source follower transistor SF1, the second source follower transistor SF2, the third source follower transistor SF3, the fourth source follower transistor SF4, the third common source transistor CS3, and the fourth common source transistor CS4.

As a result, the first intermediate signal MS1 may be composed entirely of the input signal OS2 applied to the first and second source transistors CS1 and CS2. Thus, the phase control circuit 111 may output the first intermediate signal MS1 having a phase of 90 degrees through the first output node ON1 under the above-described control of the communication processor 120.

For example, referring to FIG. 2 and FIG. 3E, the communication processor 120 may turn on the first source follower transistor SF1, the second source follower transistor SF2, and the first common source transistor CS1.

In addition, the communication processor 120 may turn off the third source follower transistor SF3, the fourth source follower transistor SF4, the second common source transistor CS2, the third common source transistor CS3, and the fourth common source transistor CS4.

The phase control circuit 111 may output a first intermediate signal MS1 having a phase of 22.5 degrees through the first output node ON1 under the above-described control of the communication processor 120. This is because the current component of the first intermediate signal MS1 derived from the source follower transistors SF1 and SF2, based on the input signal OS1 (with phase of 0 degrees) is twice that of the current component of the signal MS1 based on the input signal OS2 (with phase of 90 degrees).

Accordingly, referring collectively to FIGS. 3A to 3E, the communication processor 120 may control the phase of the first intermediate signal MS1 with a resolution of (i.e., in steps of) 22.5 degrees through the phase control circuit 111. Note that other 22.5 degree steps may be realized through analogous control of transistors as just described for FIG. 3E, i.e., by turning on just two of the source follower transistors and just one common source transistor, or by turning on just two of the common source transistors and just one source follower transistor.

The phase control circuit 111 may output a second intermediate signal MS2 based on the vector sum of at least a portion of the plurality of orthogonal signals OS1, OS2, OS3, and OS4 through the second output node ON2, under the control of the communication processor 120.

The second intermediate signal MS2 may be referred to as a signal that is differential to the first intermediate signal MS1. For example, the second intermediate signal MS2 may have a phase opposite to a phase of the first intermediate signal MS1, when analogous control of the right half circuit transistors in FIG. 2, as just described for the left half circuit transistors, is made.

The phase control circuit 111 according to an example embodiment may include a plurality of differential source follower transistors DF1, DF2, DF3, and DF4 and a plurality of differential common source transistors DS1, DS2, DS3, and DS4.

For example, the phase control circuit 111 may include a first differential source follower transistor DF1 and a second differential source follower transistor DF2, each receiving the first orthogonal signal OS1 and connected in parallel between the power supply voltage VDD and the second output node ON2.

The first differential source follower transistor DF1 may be turned on or off by an inverted control bit V1[0]_B, and the second differential source follower transistor DF2 may be turned on or off by an inverted control bit V1[1]_B.

The inverted control bit V1[0]_B may have a value inverted from the value of the control bit V1[0]. Similarly, the inverted control bit V1[1]_B may have a value inverted from the value of the control bit V1[1].

In addition, the phase control circuit 111 may include a first differential common source transistor DS1 and a second differential common source transistor DS2, each receiving the second orthogonal signal OS2 and connected in parallel between the second output node ON2 and ground.

The first differential common source transistor DS1 may be turned on or off by an inverted control bit V2[0]_B, and the second differential common source transistor DS2 may be turned on or off by an inverted control bit V2[1]_B.

The inverted control bit V2[0]_B may have a value inverted from the value of the control bit V2[0]. Similarly, the inverted control bit V2[1]_B may have a value inverted from the value of the control bit V2[1].

The first differential source follower transistor DF1 and the first differential common source transistor DS1 may be connected in series between the power supply voltage VDD and ground. Similarly, the second differential source follower transistor DF2 and the second differential common source transistor DS2 may be connected in series between the power supply voltage VDD and ground.

For example, the differential source follower transistors DF1 and DF2 receiving the first orthogonal signal OS1 and the differential common source transistors DS1 and DS2 receiving the second orthogonal signal OS2 may share a current path connected from the power supply voltage VDD to ground.

Accordingly, the first orthogonal signal OS1 and the second orthogonal signal OS2 may share a current path connected from the power supply voltage VDD to ground.

The phase control circuit 111 may include a third differential source follower transistor DF3 and a fourth differential source follower transistor DF4, each receiving the third orthogonal signal OS3 and connected in parallel between the power supply voltage VDD and the second output node ON2.

The third differential source follower transistor DF3 may be turned on or off by an inverted control bit V3[0]_B, and the fourth differential source follower transistor DF4 may be turned on or off by an inverted control bit V3[1]_B.

The inverted control bit V3[0]_B may have a value inverted from the value of the control bit V3[0]. Similarly, the inverted control bit V3[1]_B may have a value inverted from the value of the control bit V3[1].

For example, each of the plurality of differential source follower transistors DF1, DF2, DF3, and DF4 may be controlled by an inverted version of a bit voltage controlling the plurality of source follower transistors SF1, SF2, SF3, and SF4.

In addition, the phase control circuit 111 may include a third differential common source transistor DS3 and a fourth differential common source transistor DS4, each receiving the fourth orthogonal signal OS4 and connected in parallel between the second output node ON2 and the ground.

The third differential common source transistor DS3 may be turned on or off by an inverted control bit V4[0]_B, and the fourth differential common source transistor DS4 may be turned on or off by an inverted control bit V4[1]_B.

The inverted control bit V4[0]_B may have a value inverted from the value of the control bit V4[0]. Similarly, the inverted control bit V4[1]_B may have a value inverted from the value of the control bit V4[1].

For example, each of the plurality of differential common source transistors DS1, DS2, DS3, and DS4 may be controlled by an inverted version of a bit voltage controlling the plurality of common source transistors CS1, CS2, CS3, and CS4.

The third differential source follower transistor DF3 and the third differential common source transistor DS3 may be connected in series between the power supply voltage VDD and ground. Similarly, the fourth differential source follower transistor DF4 and the fourth differential common source transistor DS4 may be connected in series between the power supply voltage VDD and ground.

For example, the differential source follower transistors DF3 and DF4 receiving the third orthogonal signal OS3 and the differential common source transistors DS3 and DS4 receiving the fourth orthogonal signal OS4 may share a current path connected from the power supply voltage VDD to ground.

Accordingly, the third orthogonal signal OS3 and the fourth orthogonal signal OS4 may share a current path connected from the power supply voltage VDD to ground.

The phase control circuit 111 may output a second intermediate signal MS2 based on the vector sum of at least a portion of the plurality of orthogonal signals OS1, OS2, OS3, and OS4 through the second output node ON2, under the control of the communication processor 120.

Referring to the above-described configuration, the phase control circuit 111 according to an example embodiment may include transistors receiving different orthogonal signals and connected in series between the power supply voltage VDD and ground.

Thus, the different orthogonal signals may share at least a portion of the current path connected from the power supply voltage VDD to the ground.

As a result, the phase control circuit 111 according to an example embodiment may decrease the number of current paths required for the vector sum of the plurality of orthogonal signals OS1, OS2, OS3, and OS4.

For example, the phase control circuit 111 may include a relatively small number of transistors, compared to the case in which a current path connected from the power supply voltage VDD to ground is provided for each of the plurality of orthogonal signals OS1, OS2, OS3, and OS4.

The above-described configuration may allow the vector summing amplifier 100 according to an example embodiment to have and occupy a relatively small area. In addition, the vector summing amplifier 100 may have a relatively small area and operate at a high resolution.

The vector summing amplifier 100 according to an example embodiment may include a relatively small number of transistors to reduce performance degradation caused by parasitic elements of each transistor.

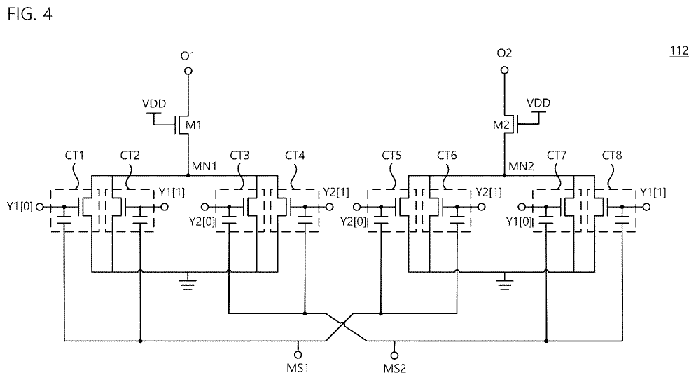

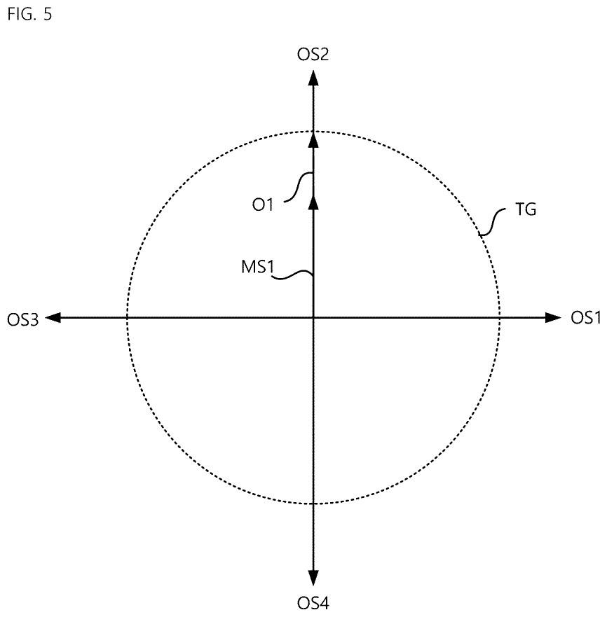

FIG. 4 is a circuit diagram of a gain compensation circuit included in a vector summing amplifier according to an example embodiment. FIG. 5 is a phasor diagram illustrating signal components to output a first output signal having a target gain TG through a gain compensation circuit according to an example embodiment.

Referring to FIG. 4, a gain compensation circuit 112 according to an example embodiment may include a plurality of compensation transistors CT1, CT2, CT3, CT4, CT5, CT6, CT7, and CT8, a first output transistor M1, and a second output transistor M2.

The gain compensation circuit 112 may include a first compensation transistor CT1, a second compensation transistor CT2, a third compensation transistor CT3, and a fourth compensation transistor CT4 connected in parallel between a first intermediate node MN1 and ground.

For example, the gain compensation circuit 112 may include a first compensation transistor CT1 and a second compensation transistor CT2, each receiving a first intermediate signal MS1 and connected in parallel between the first intermediate node MN1 and the ground.

Also, the gain compensation circuit 112 may include a third compensation transistor CT3 and a fourth compensation transistor CT4, each receiving a second intermediate signal MS2 and connected in parallel between the first intermediate node MN1 and the ground.

The first compensation transistor CT1 may be controlled by a compensation bit voltage (“compensation bit”) Y1[0]. The second compensation transistor CT2 may be controlled by a compensation bit Y1[1]. The third compensation transistor CT3 may be controlled by a compensation bit Y2[0]. The fourth compensation transistor CT4 may be controlled by a compensation bit Y2[1].

Also, the gain compensation circuit 112 may include a first output transistor M1 connected to the first intermediate node MN1. A gate electrode of the first output transistor M1 may be connected to a power supply voltage VDD.

According to an example embodiment, the first compensation transistor CT1, the second compensation transistor CT2, the third compensation transistor CT3, and the fourth compensation transistor CT4 may have different sizes.

For example, the first compensation transistor CT1 may be 20 times larger than the fourth compensation transistor CT4. The second compensation transistor CT2 may be 6 times larger than the fourth compensation transistor CT4. The third compensation transistor CT3 may be 2 times larger than the fourth compensation transistor CT4.

However, a difference in sizes between the compensation transistors CT1, CT2, CT3, and CT4 is not limited to the above examples.

According to an example embodiment, the communication processor 120 may control at least a portion of the compensation transistors CT1, CT2, CT3, and CT4 to adjust a gain of a first output signal O1 output through the first intermediate node MN1 and the first output transistor M1.

For example, the communication processor 120 may control at least a portion of the compensation transistors CT1, CT2, CT3, and CT4 to output a first output signal O1 having a target gain TG through the first intermediate node MN1 and the first output transistor M1.

According to an example embodiment, when the gain of the first intermediate signal MS1 is smaller than the target gain TG, the communication processor 120 may turn on at least a portion of the first compensation transistor CT1 and the second compensation transistor CT2.

In addition, the communication processor 120 may turn off at least a portion of the third compensation transistor CT3 and the fourth compensation transistor CT4.

Referring to FIG. 5, when the gain of the first intermediate signal MS1 having a phase of 90 degrees is smaller than the target gain TG, the communication processor 120 may control the compensation transistors CT1, CT2, CT3, and CT4 using a code corresponding to a phase of 90 degrees.

For example, the communication processor 120 may turn on the first compensation transistor CT1 and the second compensation transistor CT2. Also, the communication processor 120 may turn off the third compensation transistor CT3 and the fourth compensation transistor CT4.

The compensation bit Y1[0] may have a value of 1, the compensation bit Y1[1] may have a value of 1, the compensation bit Y2[0] may have a value of 0, and the compensation bit Y2[1] may have a value of 0. Therefore, the second control signal CTR2 illustrated in FIG. 1B may include a code of “1100” for controlling the gain compensation circuit 112. The code included in the second control signal CTR2 may be determined based on a target phase (for example, 90 degrees).

As a result, the communication processor 120 may increase the gain of the first output signal O1 output through the first intermediate node MN1 and the first output transistor M1.

For example, when the gain of the first intermediate signal MS1 is greater than the target gain TG, the communication processor 120 may turn on at least a portion of the third compensation transistor CT3 and the fourth compensation transistor CT4. Also, the communication processor 120 may turn off the second compensation transistor CT2. Also, the communication processor 120 may turn on the first compensation transistor CT1.

The (1-1)th compensation bit Y1[0] may have a value of 1, the compensation bit Y1[1] may have a value of 0, the compensation bit Y2[0] may have a value of 1, and the compensation bit Y2[1] may have a value of 1. Therefore, the second control signal CTR2 illustrated in FIG. 1B may include a code of “1011” for controlling the gain compensation circuit 112. The code included in the second control signal CTR2 may be determined based on the target phase.

A gain of the first intermediate signal MS1 transmitted through the first compensation transistor CT1 may be offset by the second intermediate signal MS2 transmitted through at least a portion of the third compensation transistor CT3 and the fourth compensation transistor CT4.

Accordingly, the communication processor 120 may reduce the gain of the first output signal O1 output through the first intermediate node MN1 and the first output transistor M1.

In addition, the gain compensation circuit 112 may include a fifth compensation transistor CT5, a sixth compensation transistor CT6, a seventh compensation transistor CT7, and an eighth compensation transistor CT8 connected in parallel between the second intermediate node MN2 and ground.

For example, the gain compensation circuit 112 may include a fifth compensation transistor CT5 and a sixth compensation transistor CT6, each receiving the first intermediate signal MS1 and connected in parallel between the second intermediate node MN2 and ground.

In addition, the gain compensation circuit 112 may include a seventh compensation transistor CT7 and an eighth compensation transistor CT8, each receiving the second intermediate signal MS2 and connected in parallel between the second intermediate node MN2 and ground.

The fifth compensation transistor CT5 may be controlled by the compensation bit Y2[0]. The sixth compensation transistor CT6 may be controlled by the compensation bit Y2[1]. The seventh compensation transistor CT7 may be controlled by the compensation bit Y1[0]. The eighth compensation transistor CT8 may be controlled by the compensation bit Y1[1].

In addition, the gain compensation circuit 112 may include a second output transistor M2 connected to the second intermediate node MN2. A gate electrode of the second output transistor M2 may be connected to the power supply voltage VDD.

According to an example embodiment, the fifth compensation transistor CT5, the sixth compensation transistor CT6, the seventh compensation transistor CT7, and the eighth compensation transistor CT8 may have different sizes.

For example, the seventh compensation transistor CT7 may be 20 times larger than the sixth compensation transistor CT6. The eighth compensation transistor CT8 may be 6 times larger than the sixth compensation transistor CT6. The fifth compensation transistor CT5 may be 2 times larger than the sixth compensation transistor CT6.

However, a difference in sizes between the compensation transistors CT5, CT6, CT7, and CT8 is not limited to the above examples.

According to an example embodiment, the communication processor 120 may control at least a portion of the compensation transistors CT5, CT6, CT7, and CT8 to adjust a gain of a second output signal O2 output through the second intermediate node MN2 and the second output transistor M2.

For example, the communication processor 120 may control at least a portion of the compensation transistors CT5, CT6, CT7, and CT8 to output a second output signal O2 having a target gain TG through the second intermediate node MN2 and the second output transistor M2.

The second output signal O2 may be referred to as a signal, differential to the first output signal O1.

Accordingly, the communication processor 120 may control the seventh compensation transistor CT7 and the eighth compensation transistor CT8 using compensation bits Y1[0] and Y1[1] controlling the first compensation transistor CT1 and the second compensation transistor CT2.

In addition, the communication processor 120 may control the fifth compensation transistor CT5 and the sixth compensation transistor CT6 using compensation bits Y2[0] and Y2[1] controlling the third compensation transistor CT3 and the fourth compensation transistor CT4.

For example, the communication processor 120 may control the gain of the second output signal O2, differential to the first output signal O1, using a control signal (or code) for controlling the gain of the first output signal O1.

Referring to the above-described configuration, the communication processor 120 may control at least one of the plurality of compensation transistors CT1 to CT8, included in the gain compensation circuit 112, based on the second control signal CTR2 (or code) determined depending on an amplification factor corresponding to a target phase. As a result, the communication processor 120 may output a differential output signal DOS having a target gain TG.

Accordingly, the vector summing amplifier 100 may be designed with relatively fewer transistors, compared to the case in which a signal in an opposite direction of the differential intermediate signal DMS is generated to achieve a uniform gain for the differential output signal DOS.

The above-described configuration may allow the vector summing amplifier 100 according to an example embodiment to have a relatively small area.

In addition, the vector summing amplifier 100 according to an example embodiment may include a relatively small number of transistors to reduce performance degradation caused by parasitic elements of each transistor.

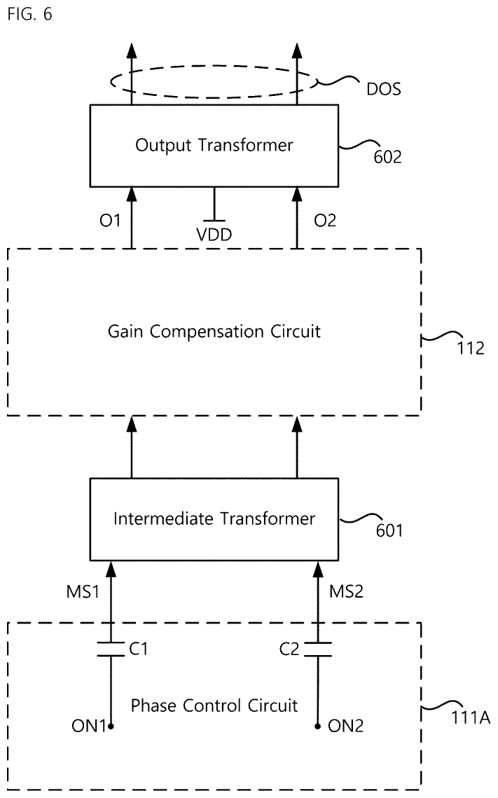

FIG. 6 is a block diagram illustrating a vector summing amplifier further including an intermediate transformer and an output transformer, according to an example embodiment.

Referring to FIG. 6, a vector summing amplifier 100B according to an example embodiment may include a phase control circuit 111A, a gain compensation circuit 112, an intermediate transformer 601, and an output transformer 602.

The vector summing amplifier 100B illustrated in FIG. 6 may be understood as an example of the vector summing amplifier 100 illustrated in FIG. 1A. For example, the phase control circuit 111A illustrated in FIG. 6 may be understood as having substantially the same configuration as the phase control circuit 111 illustrated in FIG. 1A.

Therefore, the same or substantially the same components are represented by the same reference numerals, and redundant descriptions will be omitted to avoid repetition.

The vector summing amplifier 100B may include an intermediate transformer 601 connected between the phase control circuit 111A and the gain compensation circuit 112.

According to an example embodiment, the intermediate transformer 601 may control voltage levels of a first intermediate signal MS1 and a second intermediate signal MS2 transmitted from the phase control circuit 111A.

According to an example embodiment, the phase control circuit 111A may further include a first capacitor C1 and a second capacitor C2 connected between the intermediate transformer 601 and the phase control circuit 111.

For example, the phase control circuit 111A may include a first capacitor C1 connected between the intermediate transformer 601 and a first output node ON1 of the phase control circuit 111. Also, the phase control circuit 111A may include a second capacitor C2 connected between the intermediate transformer 601 and a second output node ON2 of the phase control circuit 111.

According to an example embodiment, the first capacitor C1 and the second capacitor C2 may remove DC components (or direct current components) of the first intermediate signal MS1 and the second intermediate signal MS2, respectively.

In addition, the vector summing amplifier 100B may include an output transformer 602 connected to the gain compensation circuit 112.

According to an example embodiment, the output transformer 602 may output a differential output signal DOS based on the first output signal O1 and the second output signal O2.

For example, referring to FIGS. 4 and 6, the output transformer 602 may output a differential output signal DOS based on the first output signal O1 output from a source-drain electrode of a first output transistor M1 and the second output signal O2 output from a source-drain electrode of a second output transistor M2.

A power supply voltage VDD may be applied to a single point of the output transformer 602.

Referring to the above-described configuration, the vector summing amplifier 100B may further include transformers 601 and 602 controlling voltage levels of signals output from individual components thereof.

Thus, the vector summing amplifier 100B according to an example embodiment may perform impedance matching of a device (or system) including the vector summing amplifier 100B.

As a result, the vector summing amplifier 100B according to an example embodiment may improve the communication performance of the device (or system) including the vector summing amplifier 100B.

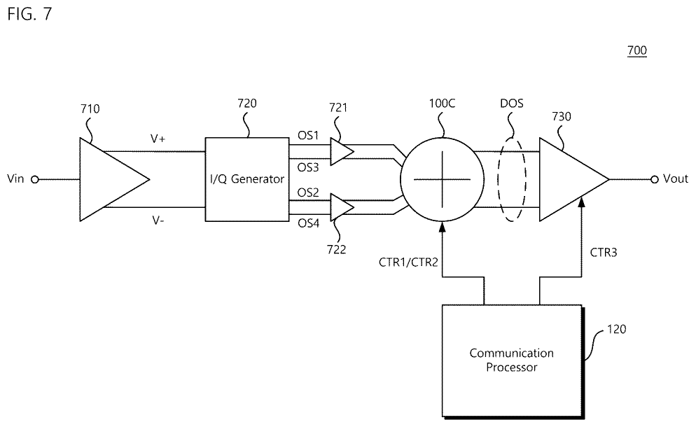

FIG. 7 is a block diagram of a phase shift device according to an example embodiment.

Referring to FIG. 7, a phase shift device 700 according to an example embodiment may include an active balun 710, a quadrature signal (I/Q) generator 720, a vector summing amplifier 100C, a variable gain amplifier 730, and a communication processor 120.

The vector summing amplifier 100C illustrated in FIG. 7 may be understood as an example of the vector summing amplifier 100 illustrated in FIG. 1A. Therefore, the same or substantially the same components are represented by the same reference numerals, and redundant descriptions will be omitted to avoid repetition.

According to an example embodiment, the phase shift device 700 may include an active balun 710 converting a single-phase input signal Vin into differential input signals V+ and V−.

For example, the active balun 710 may receive a single-phase input signal Vin and output a first differential input signal V+ and a second differential input signal V−, differential to each other.

For example, the active balun 710 may include a transmission line transformer TLT (not shown). Also, the active balun 710 may input the differential input signals V+ and V−, an output of the transmission line transformer, to the I/Q generator 720 to perform a balun function. The active balun 710 may further perform a matching network function between external components connected to the input terminal at which the input signal Vin is supplied, and the phase shift device 700.

In addition, the phase shift device 700 may include an I/Q generator 720 outputting a plurality of orthogonal signals OS1, OS2, OS3, and OS4 from the differential input signals V+ and V−.

When the differential input signals V+ AND V− are input, the I/Q generator 720 may output a plurality of orthogonal signals OS1, OS2, OS3, and OS4 corresponding to the differential input signals V+ and V−.

The plurality of orthogonal signals OS1, OS2, OS3, and OS4 may be referred to as quadrature phase signals having phases orthogonal to each other.

Therefore, the I/Q generator 720 may be implemented as (or referred to as), for example, a polyphase filter.

For example, the I/Q generator 720 may include a synthesizer generating a signal at a frequency of fLO/M, an M-fold frequency multiplier, and a 90-degree phase shift device (all not shown).

For example, the I/Q generator 720 may include a synthesizer generating a signal at a frequency of M*fLO, an M-fold frequency divider, and a 90-degree phase shift device.

Also, the I/Q generator 720 may be implemented in various forms, such as a synthesizer including a quadrature voltage-controlled oscillator (QVCO).

The plurality of orthogonal signals OS1, OS2, OS3, and OS4 may be understood as two-dimensional signals, each having a value represented as single complex number at a specific time. The complex number is divided into two parts: a real part and an imaginary part. The real part and the imaginary part are respectively called in-phase and quadrature phase components, and thus the orthogonal signals may also be referred to as I/Q signals, taking the first letters of “in-phase” and “quadrature.”

Therefore, the plurality of orthogonal signals OS1, OS2, OS3, and OS4 may include quadrature-phase signals having a phase difference of 90 degrees between each other. For example, the first orthogonal signal OS1 may be referred to as a Q+ signal, the second orthogonal signal OS2 may be referred to as an I+ signal, the third orthogonal signal OS3 may be referred to as a Q− signal, and the fourth orthogonal signal OS4 may be referred to as an I− signal.

In addition, the phase shift device 700 may include a first buffer 721 and a second buffer 722 connected between the I/Q generator 720 and the vector summing amplifier 100C.

For example, the phase shift device 700 may include a first buffer 721 transmitting the first orthogonal signal OS1 and the third orthogonal signal OS3, transmitted from the I/Q generator 720, to the vector summing amplifier 100C.

In addition, the phase shift device 700 may include a second buffer 722 transmitting the second orthogonal signal OS2 and the fourth orthogonal signal OS4, transmitted from the I/Q generator 720, to the vector summing amplifier 100C.

The first buffer 721 and the second buffer 722 according to an example embodiment may reduce an impact of impedance changes, caused by the operation of the vector summing amplifier 100C, on the I/Q generator 720.

In addition, the first buffer 721 and the second buffer 722 according to an example embodiment may amplify at least a portion of the plurality of orthogonal signals OS1, OS2, OS3, and OS4 by a specified ratio.

In addition, the phase shift device 700 may include a vector summing amplifier 100C outputting a differential output signal DOS having a target phase and a target gain TG according to the vector sum of the plurality of orthogonal signals OS1, OS2, OS3, and OS4.

For example, the vector summing amplifier 100C may generate a signal having a target phase through the vector sum of the plurality of orthogonal signals OS1, OS2, OS3, and OS4 in response to the first control signal CTR1 received from the communication processor 120.

Furthermore, the vector summing amplifier 100C may control a gain of the signal having the target phase based on an amplification factor corresponding to the target phase in response to the second control signal CTR2 received from the communication processor 120 to output a differential output signal DOS having the target phase and the target gain.

In addition, the phase shift device 700 may include a variable gain amplifier 730 outputting a single-phase output signal Vout having a conversion gain from the differential output signal DOS.

For example, the variable gain amplifier 730 may output a single-phase output signal Vout having a specified conversion gain from the differential output signal DOS having a target phase and a target gain TG under the control of the communication processor 120.

For example, the variable gain amplifier 730 may output a single-phase output signal Vout having a conversion gain from the differential output signal DOS in response to the third control signal CTR3 received from the communication processor 120.

The third control signal CTR3 may include data on the conversion gain.

In addition, the phase shift device 700 may include a communication processor 120 controlling at least a portion of the vector summing amplifier 100C and the variable gain amplifier 730.

According to an example embodiment, the communication processor 120 may control the vector summing amplifier 100C using the first control signal CTR1 and the second control signal CTR2.

For example, the communication processor 120 may control the vector summing amplifier 100C through the first control signal CTR1 to generate a differential intermediate signal DMS having a target phase through the vector sum of the plurality of orthogonal signals OS1, OS2, OS3, and OS4.

Also, the communication processor 120 may control the vector summing amplifier 100C through the second control signal CTR2 to output a differential output signal DOS having a target phase and a target gain TG from the differential intermediate signal DMS having a target phase.

The communication processor 120 may control the gain compensation circuit 112 based on a control signal (or an amplification factor) corresponding to a phase of the differential intermediate signal DMS to achieve a uniform gain for the differential output signal DOS as the target gain TG.

As a result, the vector summing amplifier 100C may be designed without transistors otherwise required in conventional vector summing amplifiers to generate a signal in an opposite direction of the differential intermediate signal DMS, to achieve a uniform gain for the differential output signal DOS.

For example, the vector summing amplifier 100C according to an example embodiment may be designed with relatively fewer transistors, compared to the case in which a signal in the opposite direction of the differential intermediate signal DMS is generated to achieve a uniform gain for the differential output signal DOS.

The above-described configurations may allow the vector summing amplifier 100C according to an example embodiment to have and occupy a relatively small area.

In addition, the communication processor 120 according to an example embodiment may control the variable gain amplifier 730 using the third control signal CTR3.

For example, the communication processor 120 may control the variable gain amplifier 730 through the third control signal CTR3 to output a single-phase output signal Vout having a conversion gain from the differential output signal DOS.

The conversion gain may be determined based on an operating (or communication) state of the electronic device or system including the phase shift device 700.

For example, the communication processor 120 may control the variable gain amplifier 730 to output a single-phase output signal Vout having a conversion gain determined based on the operating (or communication) state of the electronic device (or system) including the phase shift device 700.

Referring to the above-described configuration, the communication processor 120 according to an example embodiment may output a single-phase output signal Vout having various gains from the differential output signal DOS having a uniform target gain TG.

As a result, the phase shift device 700 according to an example embodiment may support various protocols or types of communication.

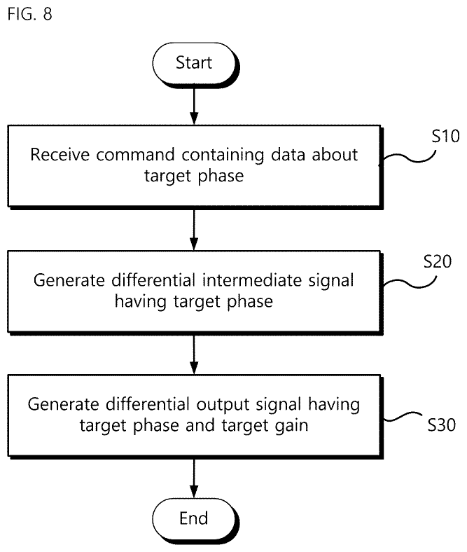

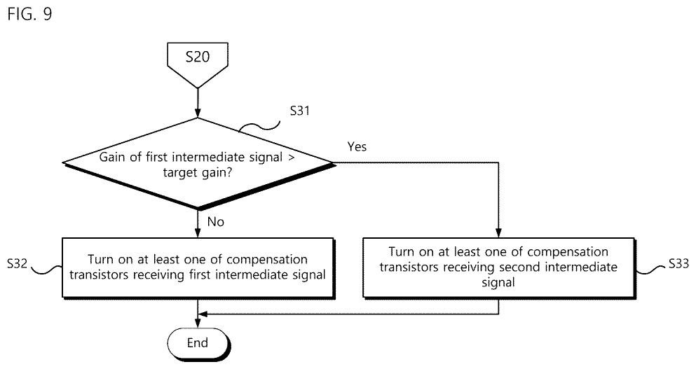

FIG. 8 is a flowchart illustrating a method of controlling a vector summing amplifier according to an example embodiment. FIG. 9 is a flowchart illustrating a method of compensating for a gain of a differential intermediate signal to output a differential output signal, according to an example embodiment.

Referring to FIG. 8, a communication processor 120 according to an example embodiment may control a phase control circuit 111 and a gain compensation circuit 112 to generate a differential output signal DOS having a target phase and a target gain TG.

In operation S10, the communication processor 120 according to an example embodiment may receive a command CMD including data on a target phase. For example, the command CMD may be understood to be transmitted from an entity (for example, an application processor) external of the vector summing amplifier 100.

In operation S20, the communication processor 120 according to an example embodiment may generate a differential intermediate signal DMS having a target phase.

For example, the communication processor 120 may generate a differential intermediate signal DMS having a target phase from a plurality of orthogonal signals OS1, OS2, OS3, and OS4 through the phase control circuit 111 in response to the command CMD.

The communication processor 120 may input a first control signal CTR1 to the phase control circuit 111 to control the phase control circuit 111 such that a differential intermediate signal DMS having a target phase is generated through a vector sum of the plurality of orthogonal signals OS1, OS2, OS3, and OS4.

For example, when the target phase is 22.5 degrees, the communication processor 120 may turn on two transistors receiving the first orthogonal signal OS1 and one transistor receiving the second orthogonal signal OS2. Also, the communication processor 120 may turn off a transistor receiving the third orthogonal signal OS3 and the transistor receiving the fourth orthogonal signal OS4.

Accordingly, the phase control circuit 111 may output a first intermediate signal MS1 having a phase of 22.5 degrees based on a vector sum of the first orthogonal signal OS1 and the second orthogonal signal OS2.

In operation S30, the communication processor 120 according to an example embodiment may generate a differential output signal DOS having a target phase and a target gain TG.

For example, the communication processor 120 may control the gain compensation circuit 112 through a second control signal CTR2 to generate a differential output signal DOS having a target phase and a target gain TG from the differential intermediate signal DMS.

The communication processor 120 may control a gain of the differential intermediate signal DMS based on an amplification factor corresponding to the target phase to generate a differential output signal DOS having a target phase and a target gain TG.

For example, the second control signal CTR2 may be understood to include data on the amplification factor corresponding to the target phase.

For example, when the target phase is 22.5 degrees, the communication processor 120 may amplify the gain of the differential intermediate signal DMS by an amplification factor corresponding to 22.5 degrees using the gain compensation circuit 112 to output a differential output signal DOS.

Referring to FIG. 9, the communication processor 120 may control at least a portion of the plurality of compensation transistors, included in the gain compensation circuit 112, through the second control signal CTR2 such that the gain compensation circuit 112 outputs a differential output signal DOS having a target gain.

For example, the communication processor 120 may control at least a portion of compensation transistors receiving a first intermediate signal MS1 through the second control signal CTR2 and compensation transistors receiving a second intermediate signal MS2 through the second control signal CTR2.

In operation S31, the communication processor 120 according to an example embodiment may determine whether a gain of the differential output signal DOS is greater than the target gain TG.

For example, the communication processor 120 may determine whether a gain of a differential intermediate signal DMS stored to correspond to the target phase is greater than the target gain TG.

In operation S32, when the gain of the first intermediate signal MS1 is smaller than the target gain, the communication processor 120 according to an example embodiment may turn on at least a portion of compensation transistors, receiving the first intermediate signal MS1, in the gain compensation circuit 112.

For example, when the gain of the first intermediate signal MS1 is smaller than the target gain, the communication processor 120 may turn on at least a portion of the compensation transistors, receive the first intermediate signal MS1, to generate a differential output signal DOS having the target gain TG.

For example, when the gain of the first intermediate signal MS1 is smaller than the target gain, the communication processor 120 may turn on the first compensation transistor CT1 and the second compensation transistor CT2 receiving the first intermediate signal MS1.

Also, the communication processor 120 may turn off the third compensation transistor CT3 and the fourth compensation transistor CT4 receiving the second intermediate signal MS2.

As a result, the gain compensation circuit 112 may output a first output signal O1 having the target gain TG through the first intermediate node MN1 connected to the compensation transistors CT1 to CT4.

In operation S33, when the gain of the first intermediate signal MS1 is greater than the target gain TG, the communication processor 120 according to an example embodiment may turn on at least a portion of compensation transistors, receiving the second intermediate signal MS2, in the gain compensation circuit 112.

For example, when the gain of the first intermediate signal MS1 is greater than the target gain TG, the communication processor 120 may turn on at least a portion of the compensation transistors, receiving the second intermediate signal MS2, to generate a differential output signal DOS having the target gain TG.

For example, when the gain of the first intermediate signal MS1 is greater than the target gain TG, the communication processor 120 may turn on at least a portion of the third compensation transistor CT3 and the fourth compensation transistor CT4 receiving the second intermediate signal MS2.

Also, the communication processor 120 may turn off the second compensation transistor CT2. Also, the communication processor 120 may turn on the first compensation transistor CT1.

A gain of the first intermediate signal MS1, transmitted to the first intermediate node MN1 through the first compensation transistor CT1, may be offset by the second intermediate signal MS2 transmitted through at least a portion of the third compensation transistor CT3 and the fourth compensation transistor CT4.

Accordingly, the communication processor 120 may reduce a gain of a first output signal O1 output through a first intermediate node MN1.

As a result, the gain compensation circuit 112 may output a first output signal O1 having the target gain TG through the first intermediate node MN1 connected to the compensation transistors CT1 to CT4.

Referring to the above-described configuration, the communication processor 120 may control the gain compensation circuit 112 based on the second control signal CTR2 or code determined according to the amplification factor corresponding to the target phase. As a result, the communication processor 120 may output a differential output signal DOS having the target gain TG.

Accordingly, the vector summing amplifier 100 according to an example embodiment may be designed with relatively fewer transistors, compared to the case in which a signal in an opposite direction of the differential intermediate signal DMS is generated to achieve a uniform gain for the differential output signal DOS.

The above-described configurations may allow the vector summing amplifier 100 according to an example embodiment to have and occupy a relatively small area.

In addition, the vector summing amplifier 100 according to an example embodiment may include a relatively small number of transistors to reduce performance degradation caused by parasitic elements of each transistor.

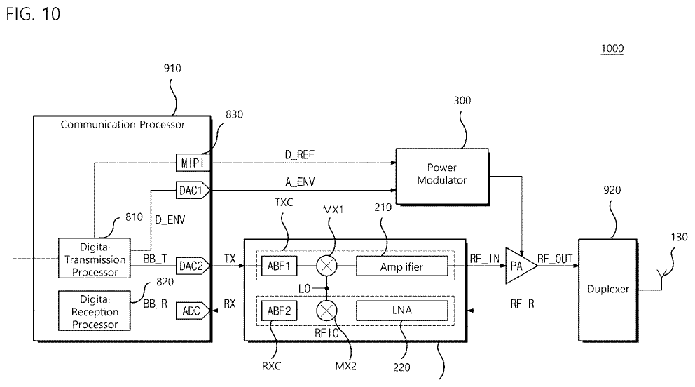

FIG. 10 is a block diagram of an electronic device according to an example embodiment.

Referring to FIG. 10, a wireless communication device 1000 according to an example embodiment may include a communication processor 910, a radio-frequency integrated circuit (RFIC) 200, a power modulator 300, a duplexer 920, a power amplifier PA, and an antenna 130.

The wireless communication device 1000 illustrated in FIG. 10 may be understood to include the vector summing amplifier 100 illustrated in FIG. 1a or the phase shift device 700 illustrated in FIG. 7. Therefore, the same or substantially the same components are represented by the same reference numerals, and redundant descriptions will be omitted to avoid repetition.

The communication processor 910 may process a baseband signal BB_T through an internal digital transmission processor 810 based on a predetermined communication scheme. Also, the communication processor 910 may process the received baseband signal BB_R through a digital reception processor 820 based on the predetermined communication scheme.

For example, the communication processor 910 may process a signal to be transmitted or a received signal based on a communication scheme such as orthogonal frequency division multiplexing (OFDM), orthogonal frequency division multiplexing access (OFDMA), wideband code multiple access (WCDMA), or high speed packet access+ (HSPA+). In addition, the communication processor 910 may process the baseband signal BB_T or BB_R based on various types of communication scheme (for example, various communication schemes to a technique for modulating or demodulating an amplitude and a frequency of the baseband signal BB_T or BB_R is applied.

The communication processor 910 may extract an envelope of the baseband signal BB_T through the digital transmission processing unit 810 and generate a digital envelope signal D_ENV based on the extracted envelope. Also, the communication processor 910 may generate an average power signal D_REF based on an average power tracking table stored in a memory. The extracted envelope may correspond to an amplitude component of the baseband signal BB_T (for example, magnitudes of an I signal and a Q signal).

The communication processor 910 may perform digital-to-analog conversion on the baseband signal BB_T and the digital envelope signal D_ENV using a plurality of digital-to-analog converters DAC1 and DAC2 provided therein to generate a transmit signal TX and an analog envelope signal A_ENV, which are analog signals, respectively. For example, the average power signal D_REF output from the communication processor 910 may be a digital signal. Accordingly, the average power signal D_REF may be provided to a digital-to-analog converter provided in the power modulator 300 through the MIPI 830, and may be converted into an analog signal, such as a reference voltage signal, through the digital-to-analog converter provided in the power modulator 300. For reference, the digital-to-analog converters DAC1 and DAC2 provided in the communication processor 910 may operate at a relatively high speed, compared to the digital-to-analog converter provided in the power modulator 300.

However, example embodiments are not limited thereto, and the communication processor 910 may output an average power signal D_REF as an analog signal through a digital-to-analog converter provided therein. The communication processor 910 may provide the average power signal, converted into an analog signal, to the power modulator 300 as a reference voltage signal.

For ease of description, an example is provided in which the communication processor 910 provides the average power signal D_REF to the digital-to-analog converter, provided in the power modulator 300, through a mobile industry processor interface (MIPI) 830.

The transmission signal TX and the analog envelope signal A_ENV may be differential signals including positive and negative signals, respectively.

Also, the communication processor 910 may receive a received signal RX, an analog signal, from the RFIC 200. Also, the communication processor 910 may extract a baseband signal BB_R, which is a digital signal, by performing analog-to-digital conversion on a receive signal RX through an analog-to-digital converter ADC provided therein. The receive signal RX may be a differential signal including a positive signal and a negative signal.

The communication processor 910 may be understood as having substantially the same configuration as the communication processor 120 illustrated in FIG. 1B.

The RFIC 200 may generate an RF input signal RF_IN by performing frequency up-conversion on the transmit signal TX, or may generate a receive signal RX by performing frequency down-conversion on the RF receive signal RF_R. For example, the RFIC 200 may include a transmit circuit TXC for frequency up-conversion, a receive circuit RXC for frequency down-conversion, and a local oscillator LO.

The transmit circuit TXC may include a first analog baseband filter (ABF1), a first mixer MX1, and an amplifier 210. For example, the first analog baseband filter ABF1 may include a low pass filter.

The first analog baseband filter ABF1 may filter the transmit signal TX received from the communication processor 910, and provide the filtered transmit signal TX to the first mixer MX1. The first mixer MX1 may perform frequency up-conversion to convert a frequency of the transmit signal TX from a baseband to a high-frequency band through a frequency signal provided by the local oscillator LO. Such frequency up-conversion may allow the transmit signal TX to be provided to the amplifier 210 as an RF input signal RF_IN and the amplifier 210 to amplify the RF input signal RF_IN firstly and provide the amplified RF input signal RF_IN to the power amplifier PA.

The transmit circuit TXC according to an example embodiment may further include a vector summing amplifier 100 illustrated in FIG. 1A. The vector summing amplifier 100 according to an example embodiment may include a phase control circuit 111 and a gain compensation circuit 112. Also, the vector summing amplifier 100 may include a communication processor 120 controlling the phase control circuit 111 and the gain compensation circuit 112.

The communication processor 120 according to an example embodiment may control the phase control circuit 111 to generate a differential intermediate signal DMS having a target phase through a vector sum of the plurality of orthogonal signals OS1, OS2, OS3, and OS4.

Also, the communication processor 120 may control the gain compensation circuit 112 to control a gain of the differential intermediate signal DMS having a target phase to output a differential output signal DOS having a target phase and a target gain.

The communication processor 120 may control the gain compensation circuit 112 based on a control signal (or an amplification factor) corresponding to the phase of the differential intermediate signal DMS to achieve a uniform gain for the differential output signal DOS as a target gain.

As a result, the vector summing amplifier 100 may be designed without transistors otherwise required in conventional amplifiers to generate a signal in an opposite direction of the differential intermediate signal DMS, to achieve a uniform gain for the differential output signal DOS.

For example, the vector summing amplifier 100 according to an example embodiment may be designed with relatively fewer transistors, compared to the case in which a signal in an opposite direction of the differential intermediate signal DMS is generated to achieve a uniform gain for the differential output signal DOS.

The above-described configurations may allow the vector summing amplifier 100 according to an example embodiment to have and occupy a relatively smaller area.

The power amplifier PA may be supplied with a power supply voltage (for example, a dynamically variable output voltage) from the power modulator 300 and may amplify power of the RF input signal RF_IN based on the supplied power supply voltage to generate an RF output signal RF_OUT. Also, the power amplifier PA may provide the generated RF output signal RF_OUT to the duplexer 920.

The receive circuit RXC may include a second analog baseband filter ABF2, a second mixer MX2, and a low-noise amplifier 220. For example, the second analog baseband filter ABF2 may include a low pass filter.

The low-noise amplifier 220 may amplify the RF receive signal RF_R provided from the duplexer 920 and provide the amplified RF receive signal RF_R to the second mixer MX2. The second mixer MX2 may perform frequency down-conversion to convert a frequency of the receive signal RF_R from a high-frequency band to a baseband through a frequency signal provided by the local oscillator LO. Such frequency down-conversion may allow the RF receive signal RF_R to be provided to the second analog baseband filter ABF2 as a received signal RX and the second analog baseband filter ABF2 to filter the receive signal RX and provide the filtered receive signal RX to the communication processor 910.

The wireless communication device 1000 may transmit a transmit signal through a plurality of frequency bands using carrier aggregation (CA). To this end, the wireless communication device 1000 may include a plurality of power amplifiers amplifying a plurality of RF input signals RF_IN, respectively corresponding to a plurality of carriers. However, for ease of description, an example is provided in which there is only one power amplifier PA.

The power modulator 300 may generate a modulated output voltage having a level, dynamically varying based on the analog envelope signal A_ENV and the average power signal D_REF, and supply the generated output voltage to the power amplifier PA as a power supply voltage.

For example, the power modulator 300 may receive the average power signal D_REF and the analog envelope signal A_ENV from the communication processor 910. Also, the power modulator 300 may generate an output voltage, dynamically varying by operating in either ET mode or APT mode, based on the received average power signal D_REF and the analog envelope signal A_ENV. Also, the power modulator 300 may supply the generated output voltage to the power amplifier PA as a power supply voltage.

When a fixed level of power supply voltage is applied to the power amplifier PA, power efficiency of the power amplifier PA may be reduced. Accordingly, to efficiently manage the power of the power amplifier PA, the power modulator 300 may modulate an input voltage (for example, power) supplied from a battery based on at least one of the analog envelope signal A_ENV and the average power signal D_REF and supply the modulated voltage to the power amplifier PA as a power supply voltage.

The duplexer 920 may separate the RF output signal RF_OUT, provided from the power amplifier PA, for each frequency band and provide the separated RF output signal RF_OUT to a corresponding antenna 130. Also, the duplexer 920 may provide an external signal, received from the antenna 130, to the low-noise amplifier 220 of the receive circuit RXC of the RFIC 200. For example, the duplexer 920 may include a front end module with integrated duplexer (FEMiD).

The antenna 130 may transmit the RF output signal RF_OUT to the outside or provide the RF receive signal RF_R received from the outside to the RFIC 200. For example, the antenna 130 may include an array antenna, but example embodiments are not limited thereto.

The communication processor 910, the power modulator 300, the RFIC 200, the power amplifier PA, and the duplexer 920 may be individually implemented as an IC, a chip, or a module. Also, the communication processor 910, the power modulator 300, the RFIC 200, the power amplifier PA, and the duplexer 920 may be mounted together on a printed circuit board (PCB). However, example embodiments are not limited thereto. In some embodiments, at least a portion of the communication processor 910, the power modulator 300, the RFIC 200, the power amplifier PA, and the duplexer 920 may be implemented as a single communication chip.

Furthermore, the wireless communication device 1000 illustrated in FIG. 10 may be included in a wireless communication system using a cellular network such as 5G or LTE, and may also be included in a wireless local area network (WLAN) system or other arbitrary wireless communication system. For reference, the configuration of the wireless communication device 1000 illustrated in FIG. 10 is only an example. Therefore, example embodiments are not limited thereto, and the wireless communication device 1000 may be configured in various ways depending on the communication protocol or communication scheme.

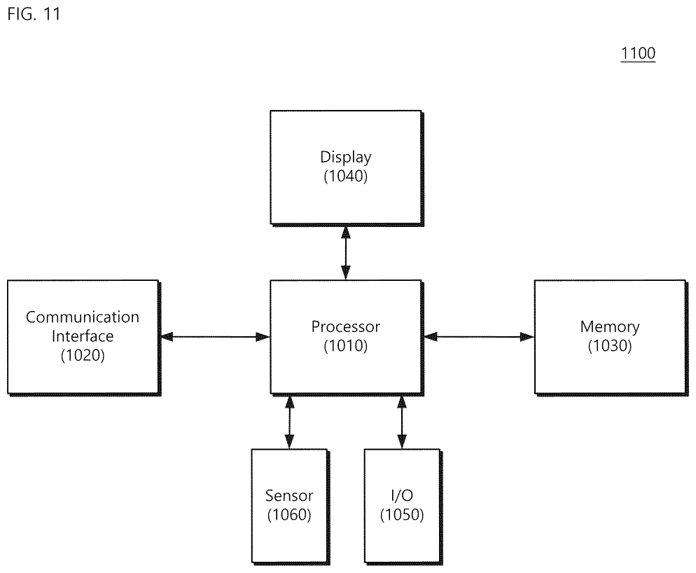

FIG. 11 is a block diagram of an IoT device including an electronic device according to an example embodiment.

Referring to FIG. 11, Internet of Things (IoT) may refer to a network between things using wired communication and/or wireless communication. An IoT device 1100 may have accessible wired or wireless interfaces and may include device transmitting or receiving data by communicating with at least one other device through the wired or wireless interfaces. The accessible interfaces of the IoT device 1100 may include a wired local area network (LAN), a wireless local area network (WLAN) such as Wi-Fi, a wireless personal area network (WPAN) such as Bluetooth, wireless universal serial bus (USB), Zigbee, near field communication (NFC), radio-frequency identification (RFID), power line communication (PCL), or modem communication interfaces that may be connected to a mobile cellular network such as 3G, LTE, 4G, or 5G. The Bluetooth interface may support Bluetooth low energy (BLE).

For example, the IoT device 1100 may include a communication interface 1020 for communicating with external devices. The communication interface 1020 may be, for example, a wired LAN interface, a wireless LAN interface such as Bluetooth, Wi-Fi, Zigbee, a PLC, or a modem communication interface that may be connected to a mobile network such as 3G, LTE, 4G, or 5G.

The communication interface 1020 may include a transceiver and/or a receiver. The communication interface 1020 illustrated in FIG. 11 may be understood to include the vector summing amplifier 100 illustrated in FIG. 1A. For example, the communication interface 1020 may include the phase control circuit 111 and the gain compensation circuit 112 illustrated in FIG. 1A.

The IoT device 1100 may transmit and/or receive information from an access point or a gateway through the transmitter and/or receiver. In addition, the IoT device 1100 may communicate with a user device or another IoT device to transmit and/or receive control information or data of the IoT device 1100.

The IoT device 1100 may include a processor 1010 performing operations. The processor 1010 illustrated in FIG. 11 may be referenced as having substantially the same configuration as the processor 120 illustrated in FIG. 1B.

The processor 1010 according to an example embodiment may control the phase control circuit 111 to generate a differential intermediate signal DMS having a target phase through a vector sum of a plurality of orthogonal signals OS1, OS2, OS3, and OS4.

Also, the processor 1010 may control a gain of the differential intermediate signal DMS having the target phase through the gain compensation circuit 112 to output a differential output signal DOS having the target phase and target gain.

The processor 1010 may control the gain compensation circuit 112 based on a control signal (or an amplification ratio) corresponding to the phase of the differential intermediate signal DMS to achieve a uniform gain for the differential output signal DOS as the target gain.

As a result, the vector summing amplifier 100 may be designed without transistors otherwise required in conventional vector summing amplifiers to generate a signal in an opposite direction of the differential intermediate signal DMS, to achieve uniform gain for the differential output signal DOS.

For example, the vector summing amplifier 100 according to an example embodiment may be designed with relatively fewer transistors, compared to the case in which a signal in an opposite direction of the differential intermediate signal DMS is generated to achieve a uniform gain for the differential output signal DOS.

The above-described configuration may allow the vector summing amplifier 100 according to an example embodiment to have a relatively small area.

The IoT device 1100 may further include a power supply that incorporates a battery for internal power supply or receives power from the outside. In addition, the IoT device 1100 may include a display 1040 displaying an internal state or data. A user may control the IoT device 1700 through a user interface UI of the display 1040 of the IoT device 1100. The IoT device 1100 may transmit the internal state and/or data to the outside through the transmitter, and may receive control a command and/or data from the outside through the receiver.

The memory 1030 may store control a command code, control data, or user data for controlling the IoT device 1100. The memory 1030 may include at least one of a volatile memory and a nonvolatile memory. The nonvolatile memory may include at least one of various types of memory such as read-only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (ReRAM), or a ferroelectric RAM (FRAM). The volatile memory may include at least one of various types of memory such as a dynamic RAM (DRAM), a static RAM (SRAM), or a synchronous DRAM (SDRAM).

According to an example embodiment, the memory 1030 may store data corresponding to a gain value corresponding to the target phase. For example, the memory 1030 may store data on a code for controlling the gain compensation circuit 112 based on the gain value corresponding to the target phase.

The code for controlling the gain compensation circuit 112 may be included in the second control signal CTR2 illustrated in FIG. 1B.

The IoT device 1100 may further include a storage device. The storage device may include at least one of nonvolatile media such as a hard disk (HDD), a solid-state drive (SSD), an embedded multimedia card (eMMC), or a universal flash storage (UFS). The storage device may store user information provided through an input/output (I/O) unit and sensing information collected through the sensor 1060.

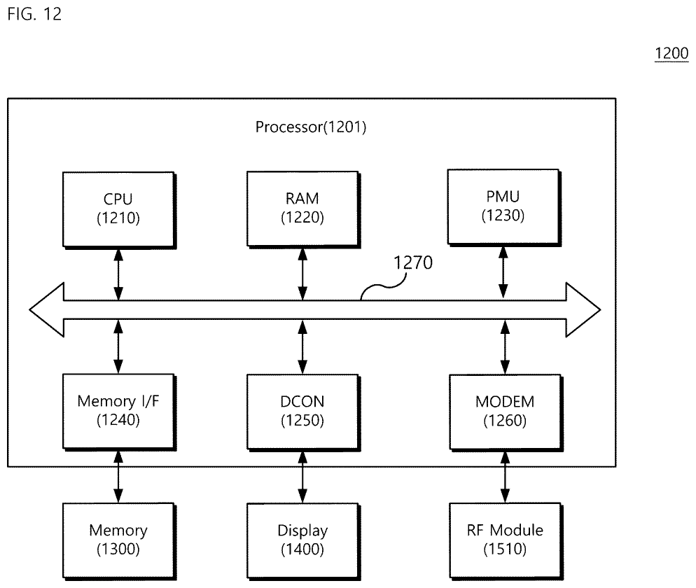

FIG. 12 is a block diagram of a mobile terminal to which an electronic device according to an example embodiment is applied.

Referring to FIG. 12, a mobile terminal 1200 may include a processor 12010, a memory 1300, a display 1400, and a radio-frequency (RF) module 1510. The mobile terminal 1800 may further include various components such as a lens, a sensor, or an audio module.

The processor 1201 may be implemented as a system-on-chip (SoC), and may include a central processing unit (CPU) 1210, a RAM 1220, a power management unit (PMU) 1230, a memory interface (Memory I/F) 1240, a display controller (DCON) 1250, a modem 1260, and a bus 1270. The processor 1201 may further include various other intellectual properties (IPs). Functions of a modem chip are integrated into the processor 1200, so that the processor 1201 may be referred to as a modem application processor (ModAP), but example embodiments are not limited thereto.

The processor 1201 illustrated in FIG. 12 may be referenced as having substantially the same configuration as the processor 120 illustrated in FIG. 1B.

The CPU 1210 may control the overall operation of the processor 1201 and the mobile terminal 1200. The CPU 1210 may control the operation of each component of the processor 1200. In addition, the CPU 1210 may be designed with a multicore architecture. The multicore architecture includes a single computing component with two or more independent cores.

The RAM 1220 may temporarily store programs, data, or instructions. For example, programs and/or data stored in memory 1300 may be temporarily stored in the RAM 1220 under the control of the CPU 1210 or based on a booting code. The RAM 1220 may be implemented as a DRAM or an SRAM.

The PMU 1230 may manage the power of each component of the processor 1201. Also, the PMU 1230 may determine an operating status of each component of the processor 1201 and control an operation thereof.

The memory interface 1240 may control the overall operation of memory 1300 and may control data exchange between each component of the processor 1201 and the memory 1300. The memory interface 1240 may write data in the memory 1300 or read data from the memory 1300 based on a request of the CPU 1210.

The display controller 1250 may transmit image data to be displayed on the display 1400 to the display 1400. The display 1400 may be implemented as a flat panel display such as a liquid crystal display (LCD) or an organic light-emitting diode (OLED), or as a flexible display.

The modem 1260 may modulate data to be transmitted to be appropriate to a wireless environment and recover received data. The modem 1260 may perform digital communication with the RF module 1510.

The RF module 1510 may convert a high-frequency signal received through the antenna 130 into a low-frequency signal and transmit the converted low-frequency signal to the modem 1260. In addition, the RF module 1510 may convert the low-frequency signal, received from the modem 1260, into a high-frequency signal and transmit the converted high-frequency signal to the outside of the mobile terminal 1800 through the antenna. The RF module 1510 may amplify or filter signals.

The RF module 1510 may include the vector summing amplifier 100 illustrated in FIG. 1A. For example, the RF module 1510 may include the phase control circuit 111 and the gain compensation circuit 112.

The processor 1201 according to an example embodiment may control the phase control circuit 111 to generate a differential intermediate signal DMS having a target phase through a vector sum of a plurality of orthogonal signals OS1, OS2, OS3, and OS4.

Also, the processor 1201 may control a gain of the differential intermediate signal DMS having a target phase through the gain compensation circuit 112 to output a differential output signal DOS having the target phase and target gain.

The processor 1201 may control the gain compensation circuit 112 based on a control signal (or an amplification factor) corresponding to a phase of the differential intermediate signal DMS to achieve a uniform gain for the differential output signal DOS to as a target gain.

As a result, the vector summing amplifier 100 may be designed without transistors otherwise required in conventional vector summing amplifiers to generate a signal in an opposite direction of the differential intermediate signal DMS, to achieve a uniform gain for the differential output signal DOS.

For example, the vector summing amplifier 100 according to an example embodiment may be designed with relatively fewer transistors, compared to the case in which a signal in an opposite direction of the differential intermediate signal DMS is generated to achieve a uniform gain for the differential output signal DOS.

The above-described configurations may allow the vector summing amplifier 100 according to an example embodiment to have a relatively small area.

As described above, the communication processor 120 according to an example embodiment may control the phase control circuit 111 to generate a differential intermediate signal DMS having a target phase through the vector sum of the plurality of orthogonal signals OS1, OS2, OS3, and OS4.

The phase control circuit 111 may include transistors receiving different orthogonal signals and connected in series between a power supply voltage VDD and ground. Thus, the different orthogonal signals may share at least a portion of a current path connected from the power supply voltage VDD to the ground.

As a result, the phase control circuit 111 according to an example embodiment may reduce the number of current paths required for a vector sum of the plurality of orthogonal signals OS1, OS2, OS3, and OS4.

For example, the phase control circuit 111 may be provided with a relatively small number of transistors, compared to the case in which the current path connected from the power supply voltage VDD to the ground is provided for each of the plurality of orthogonal signals OS1, OS2, OS3, and OS4.

The above-described configurations may allow the vector summing amplifier 100 according to an example embodiment to have a relatively small area and operate with high resolution.

Also, the communication processor 120 according to an example embodiment may control the gain of the differential intermediate signal DMS having a target phase through the gain compensation circuit 112 to output a differential output signal DOS having the target phase and target gain.

The communication processor 120 may control the gain compensation circuit 112 based on a control signal (or an amplification factor) corresponding to the phase of the differential intermediate signal DMS to achieve a uniform gain for the differential output signal DOS as a target gain.

As a result, the vector summing amplifier 100 may be designed without transistors otherwise required in conventional vector summing amplifiers to generate a signal in an opposite direction of the differential intermediate signal DMS, to achieve a uniform gain for the differential output signal DOS.

For example, the vector summing amplifier 100 according to an example embodiment may be designed with relatively fewer transistors, compared to the case in which a signal in an opposite direction of the differential intermediate signal DMS is generated to achieve a uniform gain for the differential output signal DOS.

The above-described configurations may allow the vector summing amplifier 100 according to an example embodiment to have a relatively small area.

Furthermore, the vector summing amplifier 100 according to an example embodiment may include a relatively small number of transistors to reduce performance degradation caused by parasitic elements of each transistor.

As set forth above, a vector summing amplifier according to example embodiments may have a relatively small area

While example embodiments have been shown and described above, it will be apparent to those skilled in the art that modifications and variations could be made without departing from the scope of the present inventive concept as defined by the appended claims.

What is claimed is:

1. A vector summing amplifier comprising:
a phase control circuit configured to receive a plurality of orthogonal signals and output a differential intermediate signal having a target phase through a vector sum at least a portion of the plurality of orthogonal signals;
a gain compensation circuit configured to receive the differential intermediate signal and output a differential output signal having the target phase and a target gain; and
a communication processor configured to control the phase control circuit and the gain compensation circuit,
wherein the communication processor controls a plurality of compensation transistors, included in the gain compensation circuit, based on an amplification factor corresponding to the target phase such that the gain compensation circuit outputs the differential output signal having the target gain.

2. The vector summing amplifier of claim 1, wherein the phase control circuit comprises:
a first source follower transistor and a second source follower transistor, each configured to receive a first orthogonal signal and connected in parallel with each other between a power supply voltage line and a first output node; and
a first common source transistor and a second common source transistor, each configured to receive a second orthogonal signal, orthogonal to the first orthogonal signal, and connected in parallel with each other between the first output node and ground.

3. The vector summing amplifier of claim 2, wherein the phase control circuit comprises:
a third source follower transistor and a fourth source follower transistor, each configured to receive a third orthogonal signal having a phase opposite to a phase of the first orthogonal signal and connected in parallel with each other between the power supply voltage line and the first output node; and
a third common source transistor and a fourth common source transistor, each configured to receive a fourth orthogonal signal having a phase opposite to a phase of the second orthogonal signal and connected in parallel between the first output node and the ground, and
the phase control circuit outputs a first intermediate signal based on a vector sum of at least a portion of the first orthogonal signal, the second orthogonal signal, the third orthogonal signal, and the fourth orthogonal signal.

4. The vector summing amplifier of claim 3, wherein
the phase control circuit comprises:
a first differential source follower transistor and a second differential source follower transistor, each configured to receive the first orthogonal signal and connected in parallel with each other between the power supply voltage line and a second output node; and
a first differential common source transistor and a second differential common source transistor, each configured to receive the second orthogonal signal and connected in parallel with each other between the second output node and the ground, and
the phase control circuit outputs a second intermediate signal, differential to the first intermediate signal, through the second output node.

5. The vector summing amplifier of claim 4, wherein
the gain compensation circuit comprises:
a first compensation transistor and a second compensation transistor, each configured to receive the first intermediate signal and connected in parallel with each other between the first intermediate node and the ground;
a third compensation transistor and a fourth compensation transistor, each configured receive the second intermediate signal and connected in parallel with each other between the first intermediate node and the ground; and
a first output transistor connected to the first intermediate node,
wherein the first compensation transistor, the second compensation transistor, the third compensation transistor, and the fourth compensation transistor have different sizes.

6. The vector summing amplifier of claim 5, wherein
the control processor, based on the amplification factor, causes a signal amplified at the target gain to be output through the first intermediate node by:
turning on at least a portion of the first and second compensation transistors, when a gain applied to the first intermediate signal is less than the target gain, to increase a gain applied to a signal output through the first intermediate node; and
turning on at least a portion of the third and fourth compensation transistors, when the gain of the first intermediate signal is greater than the target gain, to decrease the gain of the signal output through the first intermediate node.

7. The vector summing amplifier of claim 5, wherein
the gain compensation circuit comprises:
a fifth compensation transistor and a sixth compensation transistor, each configured to receive the first intermediate signal and connected in parallel between the second intermediate node and ground;
a seventh compensation transistor and an eighth compensation transistors, each configured to receive the second intermediate signal and connected in parallel between the second intermediate node and the ground; and
a second output transistor connected to the second intermediate node,
wherein the fifth compensation transistor, the sixth compensation transistor, the seventh compensation transistor, and the eighth compensation transistor have different sizes.

8. The vector summing amplifier of claim 7, further comprising:
an intermediate transformer connected between the phase control circuit and the gain compensation circuit,
wherein the phase control circuit further comprises a first capacitor connected between the first output node and the intermediate transformer.

9. The vector summing amplifier of claim 8, further comprising:
an output transformer configured to output the differential output signal based on a first output signal output from a source-drain electrode of the first output transistor and a second output signal output from a source-drain electrode of the second output transistor.

10. The vector summing amplifier of claim 1, wherein
the communication processor stores data indicating a code for controlling the gain compensation circuit based on the amplification factor corresponding to the target phase.

11. A phase shift device comprising:
an active balun configured to convert a single-phase input signal into a differential input signal;
an orthogonal signal generator configured to receive the differential input signal and output a plurality of orthogonal signals;
a vector summing amplifier configured to output a differential output signal having a target phase and a target gain based on the plurality of orthogonal signals;
a variable gain amplifier configured to output a single-phase output signal having a conversion gain from the differential output signal; and
a communication processor configured to control the vector summing amplifier and the variable gain amplifier,
wherein the vector summing amplifier comprises:
a phase control circuit configured to receive the orthogonal signals and output a first signal having the target phase through a vector sum of at least a portion of the plurality of orthogonal signals; and
a gain compensation circuit configured to receive the first signal and output a second signal having the target phase and a target gain,
wherein the communication processor controls a plurality of compensation transistors, included in the gain compensation circuit, based on a first amplification factor corresponding to the target phase such that the gain compensation circuit outputs a signal having the target gain.

12. The phase shift device of claim 11, wherein
the communication processor controls the variable gain amplifier in response to a command including data on the conversion gain to generate the single-phase output signal having the conversion gain from the differential output signal having the target gain.

13. The phase shift device of claim 11, wherein
the phase control circuit comprises:
a first source follower transistor and a second source follower transistor, each configured to receive a first orthogonal signal and connected in parallel between a power supply voltage and a first output node; and
a first common source transistor and a second common source transistor, each configured to receive a second orthogonal signal, orthogonal to the first orthogonal signal, and connected in parallel between the first output node and ground.

14. The phase shift device of claim 13, wherein
the phase control circuit comprises:
a third source follower transistor and a fourth source follower transistor, each configured to receive a third orthogonal signal, having a phase opposite to a phase of the first orthogonal signal, and connected in parallel between the power supply voltage and the first output node; and
a third common source transistor and a fourth common source transistor, each configured to receive a fourth orthogonal signal having a phase opposite to a phase of the second orthogonal signal, and connected in parallel between the first output node and the ground, and
the phase control circuit outputs a first intermediate signal based on a vector sum of at least a portion of the first orthogonal signal, the second orthogonal signal, the third orthogonal signal, and the fourth orthogonal signal.

15. The phase shift device of claim 14, wherein
the phase control circuit comprises:
a first differential source follower transistor and a second differential source follower transistor, each configured to receive the first orthogonal signal and connected in parallel between the power supply voltage and a second output node; and
a first differential common source transistor and a second differential common source transistor, each configured to receive the second orthogonal signal and connected in parallel between the second output node and the ground, and
the phase control circuit outputs a second intermediate signal, differential to the first intermediate signal, through the second output node.

16. The phase shift device of claim 15, wherein
the gain compensation circuit comprises:
a first compensation transistor and a second compensation transistor, each configured to receive the first intermediate signal and connected in parallel between a first intermediate node and the ground; and
a third compensation transistor and a fourth compensation transistor, each configured to receive the second intermediate signal and connected in parallel between the first intermediate node and the ground, and
the first compensation transistor, the second compensation transistor, the third compensation transistor, and the fourth compensation transistor have different sizes.

17. The phase shift device of claim 16, wherein
the control processor, based on the amplification factor, causes a signal having the target gain to be output through the first intermediate node by:
turning on at least a portion of the first and second compensation transistors, when a gain of the first intermediate signal is less than the target gain, to increase a gain of a signal output through the first intermediate node; and
turning on at least a portion of the third and fourth compensation transistors, when the gain of the first intermediate signal is greater than the target gain, to decrease the gain of the signal output through the first intermediate node.

18. The phase shift device of claim 14, further comprising:
a first buffer connected between the orthogonal signal generator and the vector summing amplifier and configured to transmit the first orthogonal signal and the third orthogonal signal to the vector summing amplifier; and
a second buffer connected between the orthogonal signal generator and the vector summing amplifier and configured to transmit the second orthogonal signal and the fourth orthogonal signal to the vector summing amplifier.

19. A method of controlling a vector summing amplifier, the method comprising:
receiving a command including data indicating a target phase;
generating a differential intermediate signal having the target phase from orthogonal signals using a phase control circuit in response to the command; and
outputting a differential output signal having the target phase and a target gain from the differential intermediate signal using a gain compensation circuit,
wherein the outputting of the differential output signal further comprises controlling a gain of the differential intermediate signal based on an amplification factor stored to correspond to the target phase.

20. The method of claim 19, wherein
the outputting the differential output signal further comprises:
turning on at least a portion of a plurality of compensation transistors, receiving the differential intermediate signal, when a gain of a first intermediate signal in the differential intermediate signal is less than the target gain; and
turning on at least a portion of a plurality of compensation transistors, receiving a second intermediate signal, differential to the first intermediate signal, when the gain of the first intermediate signal is greater than the target gain.
